(19) United States
(12) Patent Application Publication
(10) Pub. No.: US 2025/0081820 A1
(43) Pub. Date: Mar. 6, 2025

(54) DISPLAY PANEL AND MANUFACTURING METHOD FOR THE SAME

(71) Applicant: Samsung Display Co., Ltd., Yongin-si (KR)

(72) Inventors: JAESOO JUNG, Yongin-si (KR); KOHEI EBISUNO, Yongin-si (KR); MOOSOON KO, Yongin-si (KR); SUNGGEUN BAE, Yongin-si (KR); SE WAN SON, Yongin-si (KR); SANGHOON OH, Yongin-si (KR); MINWOO WOO, Yongin-si (KR); KWANHEE LEE, Yongin-si (KR); WANGWOO LEE, Yongin-si (KR); JISEON LEE, Yongin-si (KR)

(21) Appl. No.: 18/790,774

(22) Filed: Jul. 31, 2024

(30) Foreign Application Priority Data
Aug. 28, 2023 (KR) 10-2023-0113022

(51) Int. Cl. H10K 59/80; H10K 59/12; H10K 59/122; H10K 59/88

(52) U.S. Cl. CPC H10K 59/8731; H10K 59/1201; H10K 59/122; H10K 59/88

(57) ABSTRACT

A display panel includes a base layer, a pixel defining film on the base layer and including an inorganic material, a bank layer on the pixel defining film and having a plurality of pixel openings, a plurality of light-emitting elements respectively located in the plurality of pixel openings, each of the plurality of light-emitting elements including an anode, a light-emitting pattern, and a cathode, the cathode being in contact with the bank layer, and a lower encapsulation pattern on the bank layer and including a portion on the bank layer. The lower encapsulation pattern includes a first lower encapsulation pattern on the cathode and the bank layer, the first lower encapsulation pattern including a first material, and a second lower encapsulation pattern on the first lower encapsulation pattern, the second lower encapsulation pattern including a second material different from the first material, and a tip portion.

### CROSS-REFERENCE TO RELATED APPLICATION

The present application claims priority to and the benefit of Korean Patent Application No. 10-2023-0113022, filed on Aug. 28, 2023, the entire content of which is incorporated by reference herein.

### BACKGROUND

### 1. Field

The present disclosure herein relates to a display panel and a method of manufacturing a display panel, and more particularly, to a display panel with improved durability and reliability.

### 2. Description of the Related Art

Display devices, such as a television, a monitor, a smartphone, and a tablet, which provide an image to a user, include a display panel for displaying an image. Various display panels such as a liquid crystal display panel, an organic light-emitting display panel, an electro wetting display panel, and an electrophoretic display panel are being developed.

The organic light-emitting display panel may include an anode, a cathode, and a light-emitting pattern. The light-emitting pattern may be separated for each light-emitting region, and the cathode may provide a common voltage to each light-emitting region.

### SUMMARY

The present disclosure provides a display panel in which light-emitting elements are formed without using a metal mask and which has improved durability and prevents or reduces the occurrence of a defect, and a method of manufacturing the same.

One or more embodiments of the present disclosure provide a display panel including a base layer, a pixel defining film on the base layer and including an inorganic material, a bank layer on the pixel defining film and having a plurality of pixel openings, a plurality of light-emitting elements respectively located in the plurality of pixel openings, each of the plurality of light-emitting elements including an anode, a light-emitting pattern, and a cathode, the cathode being in contact with the bank layer, and a lower encapsulation pattern on the bank layer and including a portion on the bank layer. The lower encapsulation pattern includes a first lower encapsulation pattern on the cathode and the bank layer, the first lower encapsulation pattern including a first material, and a second lower encapsulation pattern on the first lower encapsulation pattern, the second lower encapsulation pattern including a second material different from the first material and a tip portion protruding in a direction away from a side surface of the first lower encapsulation pattern.

In one or more embodiments, the plurality of pixel openings may include a first pixel opening and a second pixel opening that are spaced from each other. The light-emitting element may include a first light-emitting element in the first pixel opening and including a first anode, a first light-emitting pattern, and a first cathode and a second light-emitting element in the second pixel opening and including a second anode, a second light-emitting pattern, and a second cathode.

In one or more embodiments, the lower encapsulation pattern may include a first pixel encapsulation pattern on the first cathode, and a second pixel encapsulation pattern on the second cathode. The first pixel encapsulation pattern may include a (1-1)-th lower encapsulation pattern on the first cathode and including the first material, and a (2-1)-th lower encapsulation pattern on the (1-1)-th lower encapsulation pattern, the (2-1)-th lower encapsulation pattern including the second material and a first tip portion protruding in a direction away from a side surface of the (1-1)-th lower encapsulation pattern, and the second pixel encapsulation pattern may include a (1-2)-th lower encapsulation pattern on the second cathode and including the first material, and a (2-2)-th lower encapsulation pattern on the (1-2)-th lower encapsulation pattern, the (2-2)-th lower encapsulation pattern including the second material and a second tip portion protruding in a direction away from a side surface of the (1-2)-th lower encapsulation pattern.

In one or more embodiments, a portion of the (1-2)-th lower encapsulation pattern may be located below the (2-1)-th lower encapsulation pattern and may be in contact with the (1-1)-th lower encapsulation pattern.

In one or more embodiments, the (1-2)-th lower encapsulation pattern may include a first portion on the bank layer. The first portion may include a (1-1)-th portion that does not overlap the (2-1)-th lower encapsulation pattern on a plane and a (1-2)-th portion below the (2-1)-th lower encapsulation pattern and in contact with the (1-1)-th lower encapsulation pattern, wherein an air gap may be defined in the (1-2)-th portion.

In one or more embodiments, the first portion may further include a (1-3)-th portion on the (2-1)-th lower encapsulation pattern. The (1-3)-th portion may be spaced from the (2-1)-th lower encapsulation pattern at a predetermined distance.

In one or more embodiments of the present disclosure, the display panel may further include a dummy pattern between the first portion and the bank layer and adjacent to the second pixel opening. The dummy pattern may be separated from the second light-emitting pattern and the second cathode.

In one or more embodiments, a portion of the (1-1)-th lower encapsulation pattern may be on the bank layer, and a predetermined separation portion may be defined between the bank layer and the portion of the (1-1)-th lower encapsulation pattern.

In one or more embodiments, the plurality of pixel openings may further include a third pixel opening spaced from each of the first pixel opening and the second pixel opening. The light-emitting element may further include a third light- emitting element in the third pixel opening and including a third anode, a third light-emitting pattern, and a third cathode. The lower encapsulation pattern may further include a third pixel encapsulation pattern on the third cathode.

In one or more embodiments, the third pixel encapsulation pattern may include a (1-3)-th lower encapsulation pattern on the third cathode and including the first material and a (2-3)-th lower encapsulation pattern on the (1-3)-th lower encapsulation pattern, the (2-3)-th lower encapsulation pattern including the second material and a third tip portion protruding in a direction away from a side surface of the (1-3)-th lower encapsulation pattern. A portion of the (1-3)-th lower encapsulation pattern may be below the (2-2)-th lower encapsulation pattern and may be in contact with the (1-2)-th lower encapsulation pattern.

In one or more embodiments, the second material may include silicon oxynitride, indium zinc oxide, indium gallium zinc oxide, and/or a metallic material.

In one or more embodiments, a portion of the first lower encapsulation pattern may be directly on the cathode, and a portion of the second lower encapsulation pattern may be directly on the first lower encapsulation pattern.

In one or more embodiments, each of the plurality of light-emitting elements may further include a capping pattern on the cathode.

In one or more embodiments of the present disclosure, the display panel may further include an organic encapsulation film on the second lower encapsulation pattern and providing a flat upper surface and an upper inorganic encapsulation film on the organic encapsulation film.

In one or more embodiments, the bank layer may include a first conductive layer on the pixel defining film and a second conductive layer on the first conductive layer and having an undercut shape protruding from one side of the first conductive layer.

In one or more embodiments of the present disclosure, a display panel includes a base layer, a pixel defining film on the base layer and including an inorganic material, a bank layer on the pixel defining film and having a first pixel opening and a second pixel that are spaced from each other, a plurality of light-emitting elements including a first light-emitting element in the first pixel opening and a second light-emitting element in the second pixel opening, and a lower encapsulation pattern including a first pixel encapsulation pattern on the first light-emitting element and a second pixel encapsulation pattern on the second light-emitting element. The first pixel encapsulation pattern includes a (1-1)-th lower encapsulation pattern on the first light-emitting element and a (2-1)-th lower encapsulation pattern on the (1-1)-th lower encapsulation pattern and including a first tip portion protruding in a direction away from a side surface of the (1-1)-th lower encapsulation pattern. The second pixel encapsulation pattern includes a (1-2)-th lower encapsulation pattern on the second light-emitting element and a (2-2)-th lower encapsulation pattern on the (1-2)-th lower encapsulation pattern and including a second tip portion protruding in a direction away from a side surface of the (1-2)-th lower encapsulation pattern. A portion of the (1-2)-th lower encapsulation pattern is located below the (2-1)-th lower encapsulation pattern and is in contact with the (1-1)-th lower encapsulation pattern.

In one or more embodiments of the present disclosure, a method of manufacturing a display panel includes: providing a preliminary display panel including a base layer and a bank layer on the base layer, the display panel having a first pixel opening and a second pixel opening, and including a conductive material; forming a first light-emitting element in the first pixel opening; forming a (1-1)-th preliminary lower encapsulation layer covering the first light-emitting element and the bank layer; forming a (2-1)-th preliminary lower encapsulation layer including a material different from that of the (1-1)-th preliminary lower encapsulation layer on the (1-1)-th preliminary lower encapsulation layer; patterning the (1-1)-th preliminary lower encapsulation layer and the (2-1)-th preliminary lower encapsulation layer to form a (1-1)-th lower encapsulation pattern and a (2-1)-th lower encapsulation pattern partially overlapping the first pixel opening; forming a second light-emitting element in the second pixel opening; forming a (1-2)-th preliminary lower encapsulation layer covering the second light-emitting element and the bank layer; forming a (2-2)-th preliminary lower encapsulation layer including a material different from that of the (1-2)-th preliminary lower encapsulation layer on the (1-2)-th preliminary lower encapsulation layer; and patterning the (1-2)-th preliminary lower encapsulation layer and the (2-2)-th preliminary lower encapsulation layer to form a (1-2)-th lower encapsulation pattern and a (2-2)-th lower encapsulation pattern partially overlapping the second pixel opening. A portion of the (1-2)-th lower encapsulation pattern is located below the (2-1)-th lower encapsulation pattern and is in contact with the (1-1)-th lower encapsulation pattern.

In one or more embodiments of the present disclosure, the method of manufacturing the display panel may further include forming a first photoresist pattern at least partially overlapping the first pixel opening on the (2-1)-th preliminary lower encapsulation layer prior to the patterning of the (1-1)-th preliminary lower encapsulation layer and the (2-1)-th preliminary lower encapsulation layer. The first photoresist pattern may be removed after the (1-1)-th lower encapsulation pattern and the (2-1)-th lower encapsulation pattern are formed.

In one or more embodiments, in the forming of the first light-emitting element, a first preliminary dummy layer may be formed on the bank layer. The first preliminary dummy layer may be removed together when the first photoresist pattern is removed.

In one or more embodiments, in the forming of the (1-2)-th lower encapsulation pattern and the (2-2)-th lower encapsulation pattern, a portion of the (1-2)-th lower encapsulation pattern may be on the (1-1)-th lower encapsulation pattern and the (2-1)-th lower encapsulation pattern.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1A is a combined perspective view of a display device according to one or more embodiments of the present disclosure;

FIG. 1B is an exploded perspective view of the display device illustrated in

FIG. 1A according to one or more embodiments of the present disclosure;

FIG. 2 is a cross-sectional view of a display module according to one or more embodiments of the present disclosure;

FIG. 3 is a plan view of a display panel according to one or more embodiments of the present disclosure;

FIG. 4 is an equivalent circuit diagram of a pixel according to one or more embodiments of the present disclosure;

FIG. 5 is an enlarged plan view of a portion of a display region of the display panel according to one or more embodiments of the present disclosure;

FIG. 6A is a cross-sectional view of the display panel according to one or more embodiments of the present disclosure;

FIG. 6B is a cross-sectional view of the display panel according to one or more embodiments of the present disclosure;

FIG. 6C is a cross-sectional view of the display panel according to one or more embodiments of the present disclosure; and

FIGS. 7A-7L are cross-sectional views illustrating steps of a method of manufacturing the display panel according to one or more embodiments of the present disclosure.

### DETAILED DESCRIPTION

Hereinafter, embodiments of the present disclosure will be described with reference to the drawings.

In the present disclosure, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the spirit and scope of the present disclosure. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in the present disclosure, specify the presence of stated features, integers, steps, operations, elements, components and/or groups thereof, but do not preclude the presence and/or addition of one or more other features, integers, steps, operations, elements, components, and/or groups thereof.

In the present disclosure, being “directly disposed” may mean that there is no layer, film, region, plate, and/or the like added between a part such as a layer, film, region, and/or plate and another part such as a layer, film, region, and/or plate. For example, being “directly disposed” may mean that no additional member such as an adhesive member is disposed between two layers or two members.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to one or more embodiments of the present disclosure will be described with reference to the drawings.

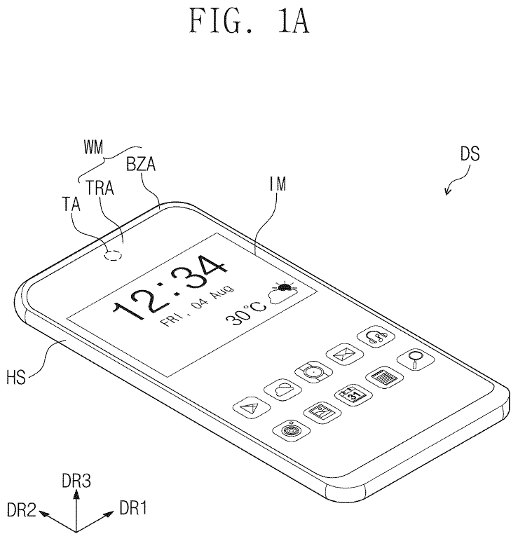

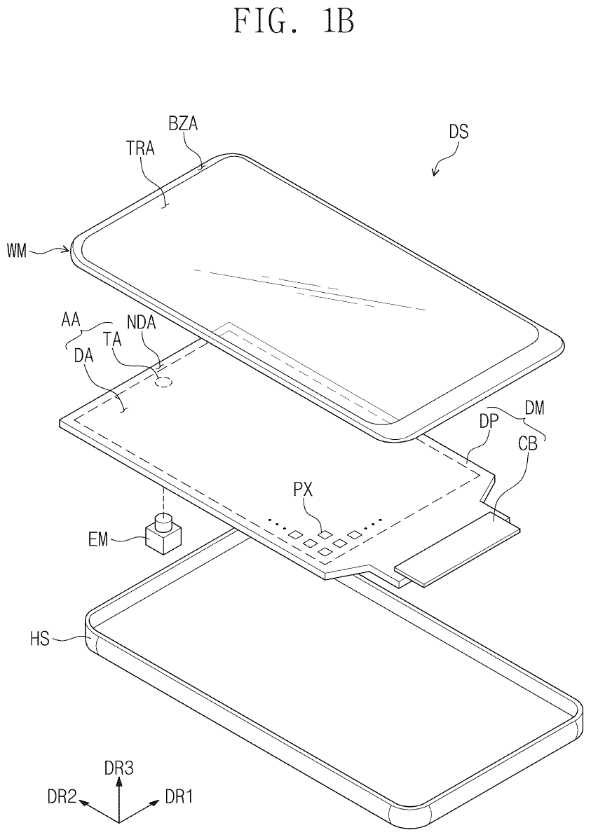

FIG. 1A is a combined perspective view of a display device according to one or more embodiments of the present disclosure. FIG. 1B is an exploded perspective view of the display device illustrated in FIG. 1A according to one or more embodiments of the present disclosure. Hereinafter, the present disclosure will be described with reference to FIGS. 1A and 1B.

The display device DS may display an image IM. For example, the display device DS may include a tablet, a laptop computer, a computer, a smart phone, a television, and/or the like. In this embodiment, the display device DS is illustrated as a smart phone as an example.

A user receives information through an image IM displayed in an active region AA. The image IM may include at least one of a static image and/or a dynamic image. FIG. 1A illustrates a clock and a plurality of icons as an example of the image IM.

The display device DS may include a window WM, a display module DM, an electronic module EM, and a housing unit HS. The window WM is coupled to the housing unit HS to form the exterior of the display device DS.

The window WM may include an optically transparent insulating material. For example, the window WM may include glass or plastic. The window WM may have a multi-layered or single-layered structure. For example, the window WM may have a stacked structure of a plurality of plastic films bonded to each other by an adhesive, or a stacked structure of a glass substrate and a plastic film bonded to each other by an adhesive.

The window WM includes a transparent region TRA and a bezel region BZA. The transparent region TRA may be an optically transparent region. An image IM generated by the display module DM may be viewed from the outside of the display device DS through the transparent region TRA.

The transparent region TRA may have a shape corresponding to that of an active region AA, which will be described later. The transparent region TRA may have a tetragonal shape parallel to each of a first direction DR1 and a second direction DR2. However, this is illustrated as an example, and the transparent region TRA may have various shapes and is not limited to any one embodiment.

The bezel region BZA is adjacent to the transparent region TRA and is around the transparent region TRA along an edge or a periphery of the transparent region TRA. The bezel region BZA may have a relatively low light transmittance, compared to the transparent region TRA. When the window WM is provided as a glass or plastic substrate, the bezel region BZA may be a color layer printed or deposited on one surface of a glass or plastic substrate. Alternatively, the bezel region BZA may be formed by coloring a corresponding region of the glass or plastic substrate.

The bezel region BZA defines the shape of the transparent region TRA. The bezel region BZA may be adjacent to and surround the transparent region TRA. However, this is illustrated as an example, and the bezel region BZA may be disposed adjacent to only one side of the transparent region TRA or may be omitted.

A direction DR3 (hereinafter referred to as a third direction) perpendicular to the transparent region TRA may correspond to the thickness direction of the display device DS. An image IM is displayed toward the third direction DR3. In this embodiment, the front surface (or upper surface) and the rear surface (or lower surface) of each member are defined based on a direction in which the image IM is displayed. The front surface and the rear surface are opposed to each other in the third direction DR3. In the present disclosure, overlapping or being spaced “on a plane” means overlapping or being spaced on a plane defined by the first direction DR1 and the second direction DR2.

In one or more embodiments, directions indicated by the first to third directions DR1, DR2, and DR3 are relative concepts and may be converted into other directions.

The display module DM is disposed between the window WM and the housing unit HS. The display module DM may be accommodated in a space provided by coupling the window WM to the housing unit HS. The display module DM may include a display panel DP and a circuit board CB.

The front surface of the display panel DP includes the active region AA and a non-active region NDA (or a non-display region) around the active region AA along an edge or a periphery of the active region AA. The active region AA may be a region in which a plurality of pixels PX are disposed. The pixels PX generate an image IM.

The active region AA includes a display region DA and a transmission region TA. The display region DA may be a region in which a plurality of light-emitting pixels from among the pixels PX are disposed, and an image IM is displayed by light generated by the light-emitting pixels. A detailed description of this will be provided later.

The transmission region TA may have a relatively high transmittance, compared to the display region DA. The transmission region TA may be a region in which a transmission pixel from among the pixels is disposed. In addition, a relatively small number of light-emitting pixels may be disposed in the transmission region TA, compared to the display region DA. For example, the density of light-emitting pixels disposed in the transmission region TA may be lower than the density of light-emitting pixels disposed in the display region DA. Alternatively, the light-emitting pixels may not be disposed in the transmission region TA.

The transmission region TA is adjacent to the display region DA. In one or more embodiments, the transmission region TA is defined as being entirely surrounded by the display region DA. However, this is illustrated as an example, and the transmission region TA may be defined at a position partially adjacent to the display region DA or may be provided in various shapes other than a circular shape, and the present disclosure is not limited to any one embodiment.

The non-active region NDA is adjacent to the active region AA. The non-active region NDA may be a region in which the pixels PX are not disposed. Driving circuits for driving the pixels PX may be disposed in the non-active region NDA.

The circuit board CB is connected to the display panel DP. The circuit board CB is illustrated as being coupled to the display panel DP in the non-active region NDA. The circuit board CB is electrically connected to the display panel DP. Various electronic elements for driving the pixels PX may be mounted on the circuit board CB. However, this is illustrated as an example, and various electronic elements for driving the pixels PX may be mounted on the display panel DP, and in this case, the circuit board CB may be omitted. The display device DS according to one or more embodiments of the present disclosure may include various embodiments, and the present disclosure is not limited to any one embodiment.

The electronic module EM is disposed between the window WM and the housing unit HS. The electronic module EM may be accommodated in a space provided by coupling the window WM to the housing unit HS. The electronic module EM is disposed to overlap the display panel DP on a plane.

On a plane, the electronic module EM overlaps the active region AA of the display panel DP and the transparent region TRA of the window WM. The electronic module EM is disposed to overlap the transmission region TA of the active region AA.

The electronic module EM may include a photographing module such as a camera, a light receiving module such as an infrared detector, a sound module such as a speaker, a module such as an ultrasonic sensor, and/or the like. In this embodiment, the electronic module EM may capture a subject existing outside the display device DS through the transmission region TA or receive an external input, such as a touch or light, which is provided to the transparent region TRA. As the electronic module EM is disposed to overlap the display panel DP, it is possible to prevent or reduce an increase in the bezel region BZA and provide a narrow-bezel display device or a borderless (e.g., a substantially borderless) display device. However, this is illustrated as an example, and the electronic module EM may be disposed to overlap the non-active region NDA and not to overlap the display panel DP, and the present disclosure is not limited to any one embodiment.

In addition, in the present disclosure, the display device DS is illustrated as a flat rigid device, but may be a foldable device. In this case, the display device DS may be folded and/or unfolded around a folding axis overlapping at least a portion of the active region AA, and the display panel DP may be provided to be flexible. The display device DS according to one or more embodiments of the present disclosure may be provided in various embodiments as long as it can display an image, and the present disclosure is not limited to any one embodiment.

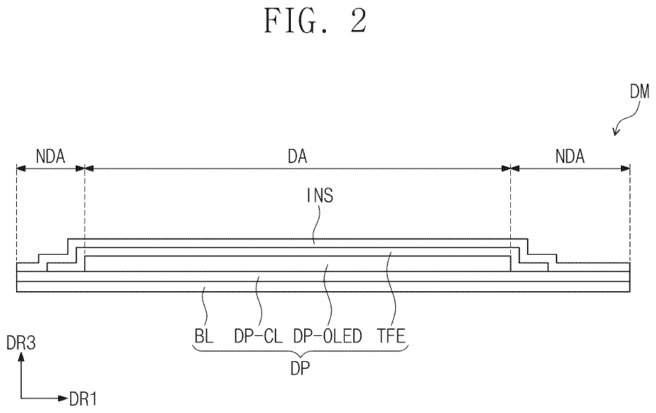

FIG. 2 is a cross-sectional view of a display module according to one or more embodiments of the present disclosure.

Referring to FIG. 2, the display module DM may include a display panel DP and an input sensor INS. In one or more embodiments, the display device DS (see FIG. 1A) according to one or more embodiments of the present disclosure may further include a protective member disposed on the lower surface of the display panel DP, or an anti-reflection member and/or a window member disposed on the upper surface of the input sensor INS.

The display panel DP may be a light-emitting display panel. However, this is an example and the present disclosure is not particularly limited thereto. For example, the display panel DP may be an organic light-emitting display panel or an inorganic light-emitting display panel. A light-emitting layer in the organic light-emitting display panel may include an organic light-emitting material. A light-emitting layer in the inorganic light-emitting display panel may include quantum dots, quantum rods, and/or micro LEDs. Hereinafter, the display panel DP will be described as an organic light-emitting display panel.

The display panel DP may include a base layer BL, a circuit element layer DP-CL disposed on the base layer BL, a display element layer DP-OLED, and a thin film encapsulation layer TFE. The input sensor INS may be disposed directly on the thin film encapsulation layer TFE. In the present disclosure, the expression “Component A is disposed directly on component B” means that no adhesive layer is disposed between component A and component B.

The base layer BL may include at least one plastic film. The base layer BL may be a flexible substrate and include a plastic substrate, a glass substrate, a metal substrate, an organic and/or inorganic composite material substrate, and/or the like. The display region DA and the non-display region NDA described with reference to FIG. 1B may be equally defined in the base layer BL.

The circuit element layer DP-CL may include at least one insulating layer and a circuit element. The insulating layer includes at least one inorganic layer and at least one organic layer. The circuit element includes signal lines, a pixel driving circuit, and/or the like.

The display element layer DP-OLED may be disposed on the circuit element layer DP-CL, and may include a bank layer and a light-emitting element.

The light-emitting element may include an anode, an intermediate layer, and a cathode.

The thin film encapsulation layer TFE may be disposed on the display element layer DP-OLED and the circuit element layer DP-CL, and may include a plurality of thin films. Some thin films may be disposed to improve optical efficiency, and other thin films may be disposed to protect organic light-emitting diodes of the display element layer DP-OLED.

The input sensor INS may be disposed on the thin film encapsulation layer TFE and the circuit element layer DP-CL, and acquires the coordinate information of an external input. The input sensor INS may have a multi-layered structure. The input sensor INS may include a single conductive layer or a plurality of conductive layers. In addition, the input sensor INS may include a single insulating layer or a plurality of insulating layers. The input sensor INS may sense an external input in a capacitive manner. However, this is an example, and the present disclosure is not limited thereto. For example, in the present disclosure, the input sensor INS may sense an external input in an electromagnetic induction manner or a pressure-sensing manner. However, the input sensor INS may be omitted.

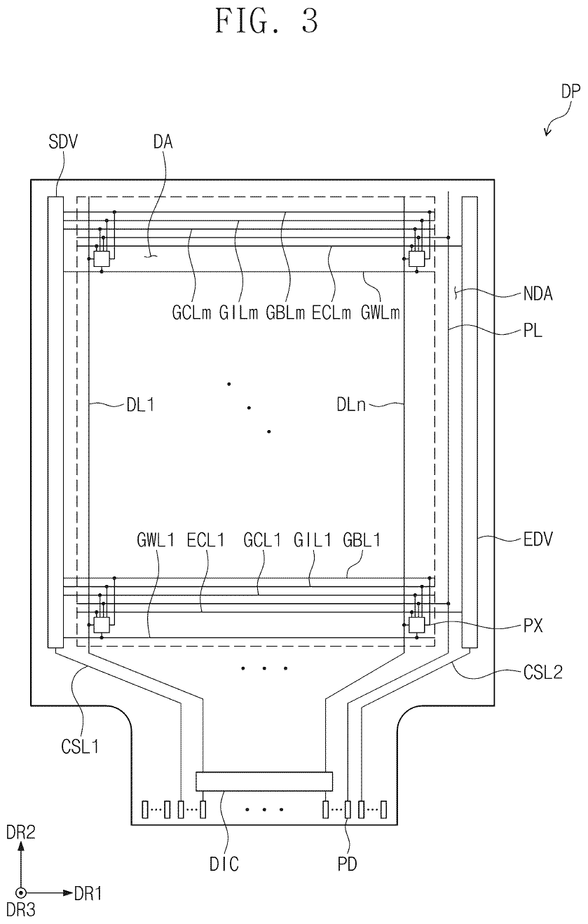

FIG. 3 is a plan view of a display panel according to one or more embodiments of the present disclosure.

Referring to FIG. 3, a display region DA and a non-display region NDA around the display region DA may be defined in the display panel DP. The display region DA and the non-display region NDA may be distinguished from each other according to whether or not pixels PX are disposed. The pixels PX may be disposed in the display region DA. A scan driver SDV, a data driver, and a light-emitting driver EDV may be disposed in the non-display region NDA. The data driver may be a portion of a circuit configured in a driving chip DIC.

The display panel DP may include pixels PX, initialization scan lines GIL1-GILm, compensation scan lines GCL1-GCLm, write scan lines GWL1-GWLm, black scan lines GBL1-GBLm, light-emitting control lines ECL1 to ECLm, data lines DL1 to DLn, first and second control lines CSL1 and CSL2, a driving voltage line PL, and a plurality of pads PD, wherein m and n are natural numbers greater than or equal to 2.

The pixels PX may be connected to the initialization scan lines GIL1-GILm, the compensation scan lines GCL1-GCLm, the write scan lines GWL1-GWLm, the black scan lines GBL1-GBLm, the light-emitting control lines ECL1-ECLm, and the data lines DL1-DLn.

The initialization scan lines GIL1-GILm, the compensation scan lines GCL1-GCLm, the write scan lines GWL1-GWLm, and the black scan lines GBL1-GBLm may extend in the first direction DR1 to be electrically connected to the scan driver SDV. The data lines DL1 to DLn may extend in the second direction DR2 to be electrically connected to the driving chip DIC. The light-emitting control lines ECL1-ECLm may extend in the first direction DR1 to be electrically connected to the light-emitting driver EDV.

The driving voltage line PL may include a portion extending in the first direction DR1 and a portion extending in the second direction DR2. The portion extending in the first direction DR1 and the portion extending in the second direction DR2 may be disposed on different layers. The driving voltage line PL may provide a driving voltage to pixels PX.

The first control line CSL1 may be connected to the scan driver SDV. The second control line CSL2 may be connected to the light-emitting driver EDV.

The driving chip DIC, the driving voltage line PL, the first control line CSL1 and the second control line CSL2 may be electrically connected to the pads PD. The circuit board CB (see FIG. 1B) may be electrically connected to the pads PD through an anisotropic conductive adhesive layer. The pads PD may connect the circuit board CB (see FIG. 1B) to the display panel DP. The pads PD may be connected to corresponding pixels PX through the driving voltage line PL, the first control line CSL1, and the second control line CSL2.

In addition, the pads PD may further include input pads. The input pads may connect the circuit board CB (see FIG. 1B) to the input sensor INS (see FIG. 2). Without being limited thereto, however, the input pads may be disposed on the input sensor INS and connected to the pads PD and a separate circuit board.

Alternatively, the input sensor INS may be omitted and may not further include the input pads.

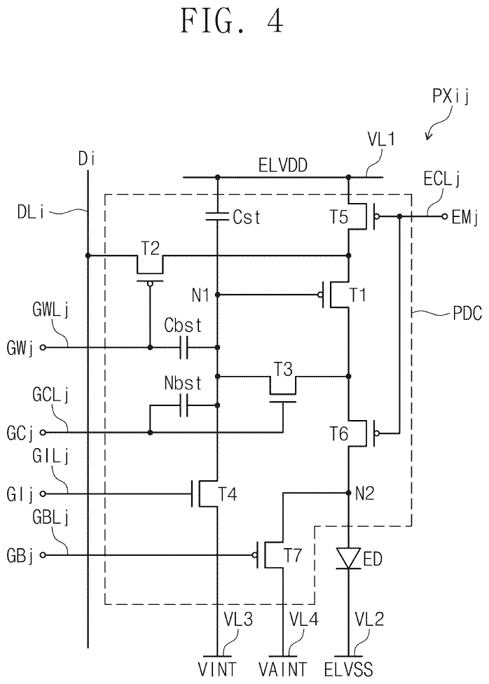

FIG. 4 is an equivalent circuit diagram of a pixel according to an embodiment of the inventive concept.

FIG. 4 exemplarily illustrates an equivalent circuit diagram of one pixel PXij from among a plurality of pixels PX (see FIG. 3). Because each of the plurality of pixels PX has a same circuit structure, the description of the circuit structure of the pixel PXij will be applied to the other pixels PX, and a detailed description of the other pixels PX will be omitted.

Referring to FIGS. 3 and 4, the pixel PXij is connected to an i-th data line DLi from among the data lines DL1-DLn, a j-th initialization scan line GILj from among the initialization scan lines GIL1-GILm, a j-th compensation scan line GCLj from among the compensation scan lines GCL1-GCLm, a j-th write scan line GWLj from among the write scan lines GWL1-GWLm, a j-th black scan line GBLj from among the black scan lines GBL1-GBLm, a j-th light-emitting control line ECLj from among the light-emitting control lines ECL1-ECLm, first and second driving voltage lines VL1 and VL2, and first and second initialization voltage lines VL3 and VL4, wherein i is an integer of 1 to n, and j is an integer of 1 to m.

The pixel PXij includes a light-emitting element ED and a pixel circuit PDC. The light-emitting element ED may be a light-emitting diode (LED). In one or more embodiments, the light-emitting element ED may be an organic light-emitting diode (OLED) including an organic light-emitting layer, but is not particularly limited thereto.

The pixel circuit PDC may control the amount of current flowing through the light-emitting element ED in response to a data signal Di. The light-emitting element ED may emit light having a suitable luminance (e.g., a predetermined luminance) in response to the amount of current provided from the pixel circuit PDC.

The pixel circuit PDC may include first to seventh transistors T1, T2, T3, T4, T5, T6, and T7, and first to third capacitors Cst, Cbst, and Nbst. The configuration of the pixel circuit PDC according to the present disclosure is not limited to the embodiment illustrated in FIG. 4. The pixel circuit PDC illustrated in FIG. 4 is only an example, and the configuration of the pixel circuit PDC may be modified and implemented.

At least one of the first to seventh transistors T1, T2, T3, T4, T5, T6, and/or T7 may have a low-temperature polycrystalline silicon (LTPS) semiconductor layer. At least one of the first to seventh transistors T1, T2, T3, T4, T5, T6, and/or T7 may have an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

Specifically, the first transistor T1, which directly affects the brightness of the light-emitting element ED, may be configured to include a semiconductor layer composed of highly reliable polycrystalline silicon, and through this, it is possible to implement a high-resolution display device. Because an oxide semiconductor has a high carrier mobility and a low leakage current, a voltage drop is not great even when a driving time is long. That is, because a color change of an image due to the voltage drop is not great even during low-frequency driving, the low-frequency driving is possible. As described above, because the oxide semiconductor has an advantage that leakage current is small, it is possible not only to prevent or reduce leakage current, which may flow to a gate electrode, but also to reduce power consumption by adopting, as an oxide semiconductor, at least one of the third transistor T3 or the fourth transistor T4 connected to the gate electrode of the first transistor T1.

Some of the first to seventh transistors T1, T2, T3, T4, T5, T6, and T7 may be P-type transistors, and others may be N-type transistors. For example, the first, second, fifth, sixth, and seventh transistors T1, T2, T5, T6, and T7 may be P-type transistors, and the third and fourth transistors T3 and T4 may be N-type transistors.

The configuration of the pixel circuit PDC according to the present disclosure is not limited to the embodiment illustrated in FIG. 4. The pixel circuit PDC illustrated in FIG. 4 is only an example, and the configuration of the pixel circuit PDC may be modified and implemented. For example, all of the first to seventh transistors T1, T2, T3, T4, T5, T6, and T7 may be P-type transistors or N-type transistors. Alternatively, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th light-emitting control line ECLj may respectively transmit, to the pixel PXij, a j-th initialization scan signal Glj, a j-th compensation scan signal GCj, a j-th write scan signal GWj, a j-th black scan signal GBj, and a j-th light-emitting control signal EMj. The i-th data line DLi transmits an i-th data signal Di to the pixel PXij. The i-th data signal Di may have a voltage level corresponding to an image signal input to the display device DS (see FIG. 1A).

The first and second driving voltage lines VL1 and VL2 may respectively transmit a first driving voltage ELVDD and a second driving voltage ELVSS to the pixel PXij. In addition, the first and second initialization voltage lines VL3 and VL4 may respectively transmit a first initialization voltage VINT and a second initialization voltage VAINT to the pixel PXij.

The first transistor T1 is connected between the light-emitting element ED and the first driving voltage line VL1 configured to receive the first driving voltage ELVDD. The first transistor T1 includes a first electrode connected to the first driving voltage line VL1 via the fifth transistor T5, a second electrode connected to a pixel electrode (or referred to as an anode) of the light-emitting element ED via the sixth transistor T6, and a third electrode (e.g., a gate electrode) connected to one end (e.g., a first node N1) of the first capacitor Cst. The first transistor T1 may receive the i-th data signal Di transmitted from the i-th data line DLi according to the switching operation of the second transistor T2 and supply a driving current to the light-emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line GWLj. The second transistor T2 may be turned on according to the write scan signal GWj received through the j-th write scan line GWLj and transmit the i-th data signal Di, which is received from the i-th data line DLi, to the first electrode of the first transistor T1. One end of the second capacitor Cbst may be connected to the third electrode (e.g., the gate electrode) of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode (e.g., the gate electrode) of the first transistor T1, a second electrode connected to the second electrode of the first transistor T1, and a third electrode (e.g., a gate electrode) connected to the j-th compensation scan line GCLj. The third transistor T3 may be turned on according to the j-th compensation scan signal GCj received through the j-th compensation scan line GCLj so that the third electrode (e.g., the gate electrode) of the first transistor T1 and the second electrode of the first transistor T1 are connected to each other, thus being able to diode-connect the first transistor T1 (e.g., the first transistor may be diode-connected). One end of the third capacitor Nbst may be connected to the third electrode (e.g., the gate electrode) of the third transistor T3, and the other end of the third capacitor Nbst may be connected to the first node N1.

The fourth transistor T4 is connected between the first node N1 and the first initialization voltage line VL3 to which the first initialization voltage VINT is applied. The fourth transistor T4 includes a first electrode connected to the first initialization voltage line VL3 to which the first initialization voltage VINT is transmitted, a second electrode connected to the first node N1, and a third electrode (e.g., a gate electrode) connected to the j-th initialization scan line GILj. The fourth transistor T4 is turned on according to the j-th initialization scan signal Glj received through the j-th initialization scan line GILj. The turned-on fourth transistor T4 transmits the first initialization voltage VINT to the first node N1 to initialize the potential (i.e., the potential of the first node N1) of the third electrode (e.g., the gate electrode) of the first transistor T1.

The fifth transistor T5 includes a first electrode connected to the first driving voltage line VL1, a second electrode connected to the first electrode of the first transistor T1, and a third electrode (e.g., a gate electrode) connected to the j-th light-emitting control line ECLj. The sixth transistor T6 includes a first electrode connected to the second electrode of the first transistor T1, a second electrode connected to the pixel electrode of the light-emitting element ED, and a third electrode (e.g., a gate electrode) connected to the j-th light-emitting control line ECLj.

The fifth and sixth transistors T5 and T6 are concurrently (e.g., simultaneously) turned on according to the j-th light-emitting control signal EMj received through the j-th light-emitting control line ECLj. The first driving voltage ELVDD applied through the turned-on fifth transistor T5 may be compensated through the diode-connected first transistor T1 and then transmitted to the light-emitting element ED through the sixth transistor T6.

The seventh transistor T7 includes a first electrode connected to the second initialization voltage line VL4 to which the second initialization voltage VAINT is transmitted, a second electrode connected to the second electrode of the sixth transistor T6 (e.g., a second node N2), and a third electrode (e.g., a gate electrode) connected to the black scan line GBLj. The second initialization voltage VAINT may have a voltage level equal to or lower than that of the first initialization voltage VINT. The seventh transistor T7 is turned on according to the j-th black scan signal GBj received through the j-th black scan line GBLj.

One end of the first capacitor Cst is connected to the third electrode of the first transistor T1 (e.g., the first node N1), and the other end of the first capacitor Cst is connected to the first driving voltage line VL1. The cathode of the light-emitting element ED may be connected to the second driving voltage line VL2 configured to transmit the second driving voltage ELVSS. The second driving voltage ELVSS may have a lower voltage level than the first driving voltage ELVDD.

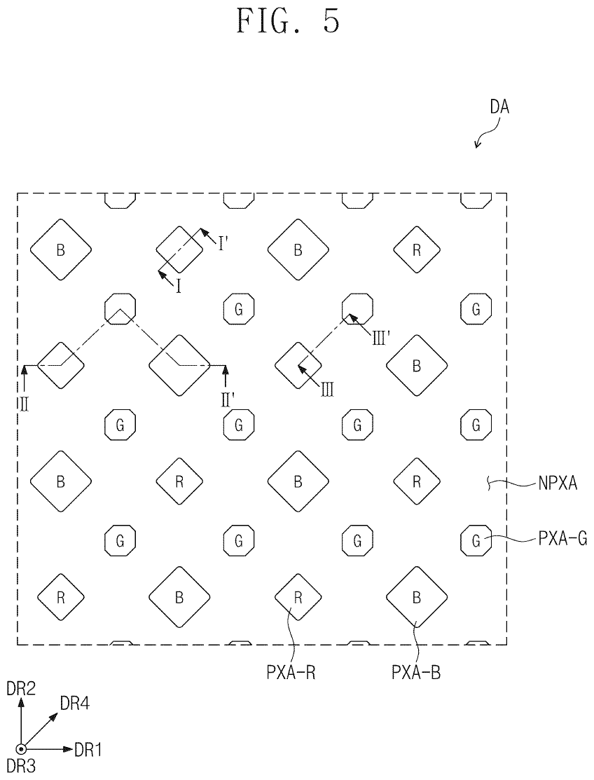

FIG. 5 is an enlarged plan view of a portion of a display region of the display panel according to one or more embodiments of the present disclosure. FIG. 5 illustrates a plane of the display module DM viewed from the display surface IS (see FIG. 1B) of the display module DM (see FIG. 1B) and shows an arrangement of the light-emitting regions PXA-R, PXA-G, and PXA-B.

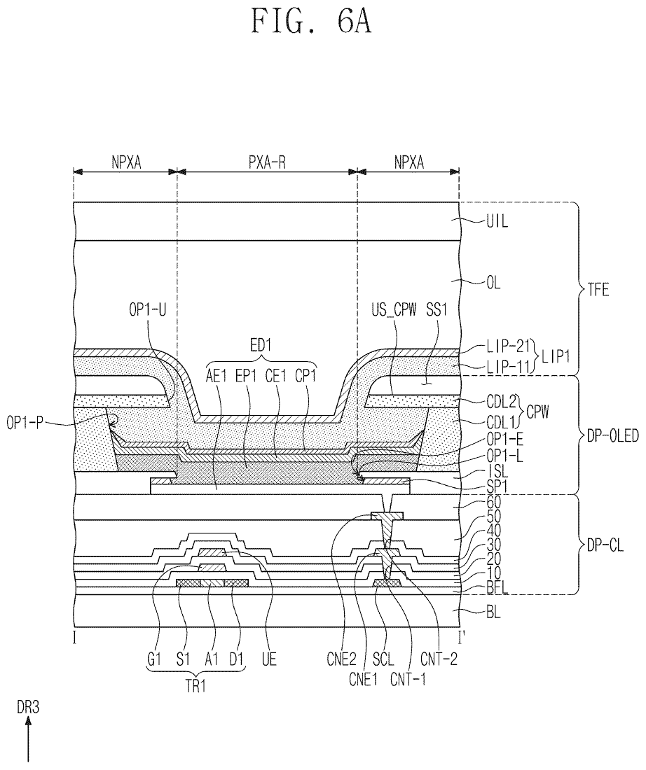

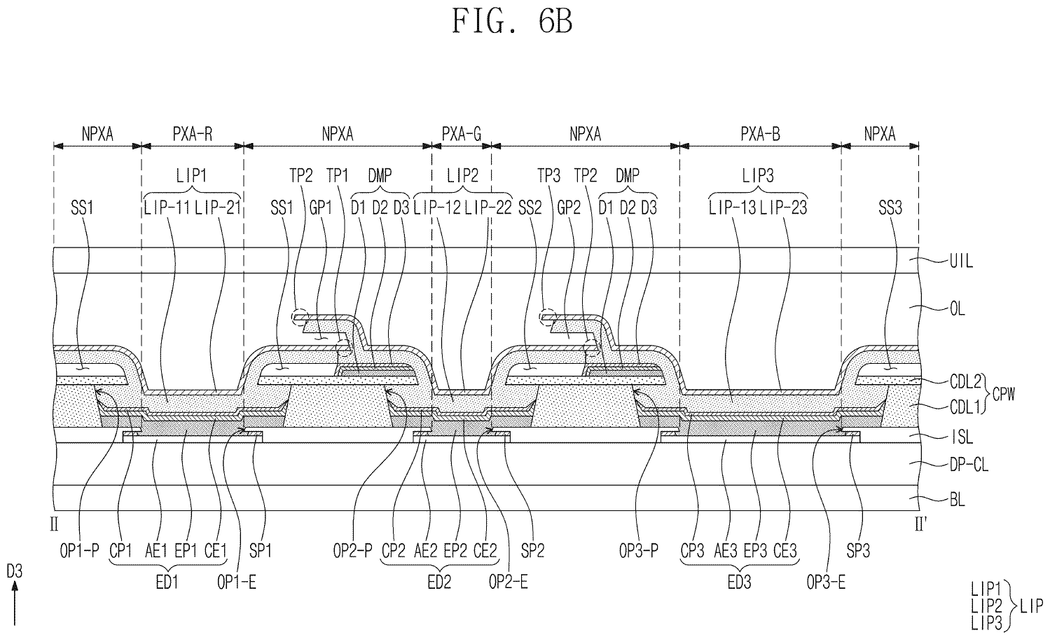

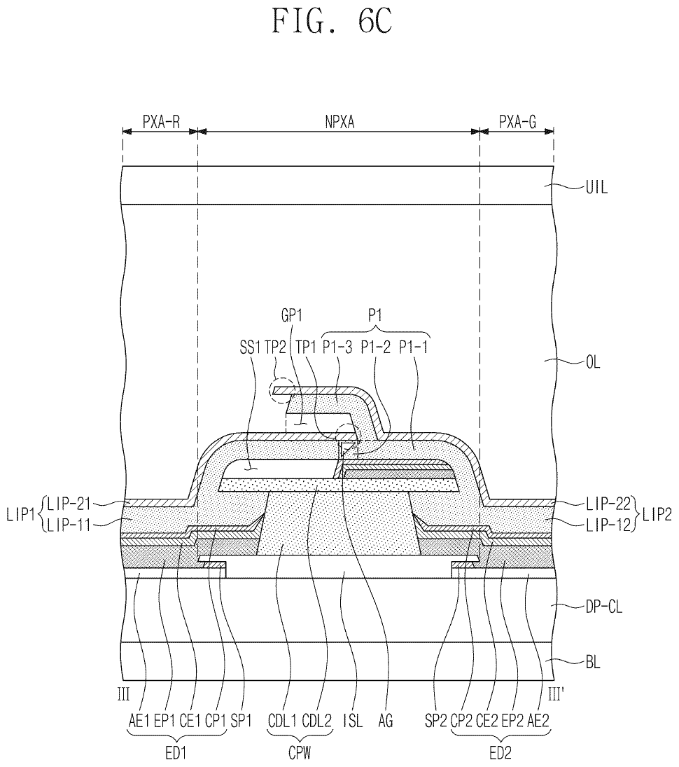

Referring to FIG. 5, the display region DA may include first to third light-emitting regions PXA-R, PXA-G, and PXA-B and a peripheral region NPXA around the first to third light-emitting regions PXA-R, PXA-G, and PXA-B. The first to third light-emitting regions PXA-R, PXA-G, and PXA-B may respectively correspond to regions from which light provided from light-emitting elements ED1, ED2, and ED3 (see FIG. 6B) is emitted. The first to third light-emitting regions PXA-R, PXA-G, and PXA-B may be classified according to the color of light emitted toward the outside of the display module DM (see FIG. 2).

The first to third light-emitting regions PXA-R, PXA-G, and PXA-B may respectively provide first to third color lights having different colors. For example, the first color light may be red light, the second color light may be green light, and the third color light may be blue light. However, the first to third color lights are not necessarily limited to the above examples.

Each of the first to third light-emitting regions PXA-R, PXA-G, and PXA-B may be defined as a region in which the upper surface of the anode is exposed by a light-emitting opening to be described later. The peripheral region NPXA sets boundaries between the first to third light-emitting regions PXA-R, PXA-G, and PXA-B and may prevent color mixing between the first to third light-emitting regions PXA-R, PXA-G, and PXA-B.

Each of the first to third light-emitting regions PXA-R, PXA-G, and PXA-B may be provided in plurality and they may be repeatedly arranged in a suitable arrangement (e.g., a predetermined arrangement) form in the display region DA. For example, the first and third light-emitting regions PXA-R and PXA-B may be alternately arranged along the first direction DR1 to form a ‘first group’. The second light-emitting regions PXA-G may be arranged along the first direction DR1 to form a ‘second group’. Each of the ‘first group’ and the ‘second group’ may be provided in plurality, and the ‘first groups’ and the ‘second groups’ may be alternately arranged along the second direction DR2.

One second light-emitting region PXA-G may be disposed to be spaced from one first light-emitting region PXA-R or one third light-emitting region PXA-B in a fourth direction DR4 (e.g., a diagonal direction). The fourth direction DR4 may be defined as a direction between the first and second directions DR1 and DR2.

FIG. 5 illustrates, as an example, an arrangement form of the first to third light-emitting regions PXA-R, PXA-G, and PXA-B, but the arrangement form thereof is not limited thereto and they may be arranged in various forms. In one or more embodiments of the present disclosure, the first to third light-emitting regions PXA-R, PXA-G, and PXA-B may have a PENTILE® arrangement form as illustrated in FIG. 5. Alternatively, the first to third light-emitting regions PXA-R, PXA-G, and PXA-B may have a stripe arrangement form or a Diamond Pixel® arrangement form. PENTILE® and Diamond Pixel® are registered trademarks of Samsung Display Co., Ltd., Republic of Korea.

The first to third light-emitting regions PXA-R, PXA-G, and PXA-B may have various shapes on a plane (e.g., in a plan view). For example, the first to third light-emitting regions PXA-R, PXA-G, and PXA-B may have polygonal, circular, and/or elliptical shapes. For example, FIG. 5 illustrates, on a plane, the first and third light-emitting regions PXA-R and PXA-B having a quadrangular shape (or a diamond shape) and the second light-emitting region PXA-G having an octagonal shape.

The first to third light-emitting regions PXA-R, PXA-G, and PXA-B may have a same shape on a plane, or at least some of them may have different shapes. For example, FIG. 5 illustrates, on a plane, the first and third light-emitting regions PXA-R and PXA-B having a same shape and the second light-emitting region PXA-G having a shape different from those of the first and third light-emitting regions PXA-R and PXA-B.

At least some of the first to third light-emitting regions PXA-R, PXA-G, and PXA-B may have different areas on a plane. In one or more embodiments of the present disclosure, the area of the first light-emitting region PXA-R configured to emit red light may be larger than the area of the second light-emitting region PXA-G configured to emit green light and smaller than the area of the third light-emitting region PXA-B configured to emit blue light. However, the size relationship between the areas of the first to third light-emitting regions PXA-R, PXA-G, and PXA-B according to the color of emitted light is not limited thereto and may vary depending on the design of the display module DM (see FIG. 2). In addition, without being limited thereto, the first to third light-emitting regions PXA-R, PXA-G, and PXA-B may have a same area on a plane.

In one or more embodiments, the shape, area, and arrangement of the first to third light-emitting regions PXA-R, PXA-G, and PXA-B of the display module DM (see FIG. 2) according to the present disclosure may be designed in various ways according to the color of emitted light or the size and configuration of the display module DM (see FIG. 2), and the present disclosure is not limited to the embodiment illustrated in FIG. 5.

FIG. 6A is a cross-sectional view of the display panel according to one or more embodiments of the present disclosure. FIG. 6A illustrates a cross section taken along the line I-I′ of FIG. 5. FIG. 6A will be described with reference to FIG. 2, and the descriptions of the same reference numerals will be omitted.

FIG. 6A is an enlarged view of one light-emitting region PXA-R in the display region DA (see FIG. 5), and FIG. 6A illustrates, as an example, the shape of the first light-emitting region PXA-R, but a similar description may be applied to the second light-emitting region PXA-G and the third light-emitting region PXA-B.

Referring to FIG. 6A, the display panel DP may include a base layer BL, a circuit element layer DP-CL, a display element layer DP-OLED, and a thin film encapsulation layer TFE.

The display panel DP may include a plurality of insulating layers, a semiconductor pattern, a conductive pattern, a signal line, and/or the like. An insulating layer, a semiconductor layer, and a conductive layer are formed by a method such as coating and/or deposition. Hereafter, the insulating layer, the semiconductor layer, and the conductive layer may be selectively patterned through photolithography and etching processes. In this way, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include a buffer layer BFL, a transistor TR1, a signal transmission region SCL, first to sixth insulating layers 10, 20, 30, 40, 50, and 60, an upper electrode UE, and a plurality of connection electrodes CNE1 and CNE2.

The buffer layer BFL may be disposed on the base layer BL. The buffer layer BFL may improve bonding strength between the base layer BL and the semiconductor pattern. The buffer layer BFL may include a silicon oxide layer and a silicon nitride layer. The silicon oxide layer and the silicon nitride layer may be alternately stacked on each other.

The semiconductor pattern may be disposed on the buffer layer BFL. The semiconductor pattern may include polysilicon. Without being limited thereto, however, the semiconductor pattern may include amorphous silicon or metal oxide. FIG. 6A illustrates, as an example, only a portion of the semiconductor pattern, and the semiconductor pattern may be further disposed in the plurality of light-emitting regions PXA-R, PXA-G, and PXA-B (see FIG. 5). The semiconductor pattern may be arranged in a specific rule across the plurality of light-emitting regions PXA-R, PXA-G, and PXA-B. The semiconductor pattern may have different electrical properties depending on whether it is doped or not. The semiconductor pattern may include a first region having a high doping concentration and a second region having a low doping concentration. The first region may be doped with an N-type dopant or a P-type dopant. A P-type transistor may include the first region doped with a P-type dopant.

The first region has higher conductivity than the second region and substantially serves as an electrode or a signal line. The second region may substantially correspond to an active (or channel) of a transistor. In other words, a portion of the semiconductor pattern may be an active region of a transistor, another portion thereof may be a source or a drain region of a transistor, and still another portion thereof may be a conductive region.

A source S, an active region A, and a drain D of the transistor TR1 may be formed from the semiconductor pattern. FIG. 6A illustrates a portion of the signal transmission region SCL formed from the semiconductor pattern. In one or more embodiments, the signal transmission region SCL may be connected to the drain D of the transistor TR1 on a plane.

The first to sixth insulating layers 10, 20, 30, 40, 50, and 60 may be disposed above the buffer layer BFL. The first to sixth insulating layers 10, 20, 30, 40, 50, and 60 may be inorganic layers or organic layers.

The first insulating layer 10 may be disposed on the buffer layer BFL. The first insulating layer 10 may cover the source S, the active region A, and the drain D of the transistor T1 and the signal transmission region SCL which are disposed on the buffer layer BFL. A gate G of the transistor TR1 may be disposed on the first insulating layer 10 and may overlap the active region A of the transistor T1 in the third direction DR3. The second insulating layer 20 may be disposed on the first insulating layer 10 to cover the gate G. The upper electrode UE may be disposed on the second insulating layer 20. The third insulating layer 30 may be disposed on the second insulating layer 20 to cover the upper electrode UE.

The first connection electrode CNE1 may be disposed on the third insulating layer 30. The first connection electrode CNE1 may be connected to the signal transmission region SCL through a contact hole CNT-1 passing through the first to third insulating layers 10, 20, and 30. The fourth insulating layer 40 may be disposed on the third insulating layer 30 to cover the first connection electrode CNE1. The fourth insulating layer 40 may be an organic layer. The fifth insulating layer 50 may be disposed on the fourth insulating layer 40.

The second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50. The sixth insulating layer 60 may be disposed on the fifth insulating layer 50 to cover the second connection electrode CNE2. The fifth insulating layer 50 may be an organic layer.

The display element layer DP-OLED may be disposed on the circuit element layer DP-CL. The display element layer DP-OLED may include a light-emitting element ED1, a sacrificial pattern SP1, a pixel defining film ISL, and a bank layer CPW.

The light-emitting element ED1 may include an anode AE1 (or first electrode or the first anode AE1), a light-emitting pattern EP1 (e.g., the first light-emitting pattern EP1), and a cathode CE1 (or second electrode or a first cathode CE1). Each of the first to third light-emitting elements ED1, ED2, and ED3 to be described later may have substantially the same configuration as the light-emitting element ED1 of FIG. 6A. The descriptions of the anode AE1, the light-emitting pattern EP1, and the cathode CE1 may be equally applied to all of the anode, the light-emitting pattern, and the cathode of each of the first to third light-emitting elements to be described later.

The anode AE1 may be disposed on the sixth insulating layer 60 of the circuit element layer DP-CL. The anode AE1 may be a transmissive electrode, a semi-transmissive electrode, and/or a reflective electrode. The anode AE1 may be connected to the second connection electrode CNE2 through a connection contact hole passing through the sixth insulating layer 60. Accordingly, the anode AE1 may be electrically connected to the signal transmission region SCL through the first and second connection electrodes CNE1 and CNE2 so as to be electrically connected to a corresponding circuit element. The anode AE1 may have a single-layered or multi-layered structure. The anode AE1 may include a plurality of layers including ITO and/and Ag. For example, the anode AE1 may include a layer (hereinafter referred to as a lower ITO layer) including ITO, a layer (hereinafter referred to as an Ag layer) disposed on the lower ITO layer and including Ag, and a layer (hereinafter referred to as an upper ITO layer) disposed on the Ag layer and including ITO.

The sacrificial pattern SP1 may be disposed between the anode AE1 and the pixel defining film ISL. The sacrificial pattern SP1 may correspond to a portion of a layer provided to prevent the anode AE1 from being damaged in a process of forming a pixel opening OP1-P which will be described later. A sacrificial opening OP1-L configured to expose a portion of the upper surface of the anode AE1 may be defined in the sacrificial pattern SP1. The sacrificial opening OP1-L may overlap a light-emitting opening OP1-E which will be described later. The sacrificial pattern SP1 may include amorphous transparent conductive oxide. For example, the sacrificial pattern SP1 may include zinc oxide (ZnOₓ) doped with aluminum (Al).

The pixel defining film ISL may be disposed on the sixth insulating layer 60 of the circuit element layer DP-CL. The light-emitting opening OP1-E may be defined in the pixel defining film ISL. The light-emitting opening OP1-E may correspond to the anode AE, and the pixel defining film ISL may expose at least a portion of the anode AE through the light-emitting opening OP1-E.

In addition, the light-emitting opening OP1-E may correspond to the sacrificial opening OP1-L of the sacrificial pattern SP1. According to this embodiment, the upper surface of the anode AE1 may be spaced from the pixel defining film ISL on a cross section with the sacrificial pattern SP1 interposed therebetween, and accordingly, in a process of forming the light-emitting opening OP1-E, damage to the anode AE1 may be prevented.

On a plane, the area of the light-emitting opening OP1-E may be smaller than that of the sacrificial opening OP1-L. That is, an inner side surface of the pixel defining film ISL defining the light-emitting opening OP1-E may be closer to the center of the anode AE1 than an inner side surface of the sacrificial pattern SP1 defining the sacrificial opening OP1-L. Without being limited thereto, however, the inner side surface of the sacrificial pattern SP1 defining the sacrificial opening OP1-L may be substantially aligned with the inner side surface of the pixel defining film ISL defining a corresponding light-emitting opening OP1-E. In this case, the light-emitting region PXA-R may be regarded as a region of the anode AE1 exposed from a corresponding sacrificial opening OP1-L.

The pixel defining film ISL may include an inorganic insulating material. The pixel defining film ISL may include at least one of silicon oxide (SiOₓ), silicon nitride (SiNₓ), and/or silicon oxynitride (SiOₓN_{y}). For example, silicon nitride (SiNₓ) may be included therein. The pixel defining film ISL may be disposed between the anode AE and the bank layer CPW to block electrical connection between the anode AE and the bank layer CPW.

The bank layer CPW may be disposed on the pixel defining film ISL. The pixel opening OP1-P may be defined in the bank layer CPW. The pixel opening OP1-P may correspond to the light-emitting opening OP1-E and expose at least a portion of the anode AE.

The bank layer CPW may have an undercut shape on a cross section. The bank layer CPW may include a plurality of layers sequentially stacked on each other, and at least one of the plurality of layers may be recessed compared to the other layers. At least one of the plurality of layers included in the bank layer CPW may protrude compared to the other layers. Accordingly, the bank layer CPW may include a tip structure.

In this embodiment, the bank layer CPW may include a first conductive layer CDL1 and a second conductive layer CDL2. Each of the first conductive layer CDL1 and the second conductive layer CDL2 may include a conductive material. The first conductive layer CDL1 may be disposed on the pixel defining film ISL and have a first conductivity and a first thickness. The second conductive layer CDL2 may be disposed on the first conductive layer CDL1 and have a second conductivity lower than the first conductivity and a second thickness smaller than the first thickness.

An etch rate of the first conductive layer CDL1 may be higher than an etch rate of the second conductive layer CDL2. That is, the first conductive layer CDL1 may include a material having a higher etching selectivity than the second conductive layer CDL2.

In one or more embodiments of the present disclosure, each of the first and second conductive layers CDL1 and CDL2 may include a metallic material. In addition, in one or more embodiments of the present disclosure, the second conductive layer CDL2 may include a material having a lower reflectance than the first conductive layer CDL1 and so it is possible to reduce the reflectance of the upper surface of the second conductive layer CDL2 which substantially forms an upper surface US_CPW of the bank layer CPW, thus being able to improve the display quality of the display panel DP. For example, the first conductive layer CDL1 may include aluminum (AI), and the second conductive layer CDL2 may include titanium (Ti). However, the materials of the first and second conductive layers CDL1 and CDL2 are not limited to any one embodiment.

In this embodiment, the bank layer CPW may receive a bias voltage. Accordingly, the bias voltage may be provided to the cathode CE1 in contact with the bank layer CPW.

In this embodiment, on a plane, a first upper opening OP1-U defined in the second conductive layer CDL2 may overlap the pixel opening OP1-P defined in the first conductive layer CDL1, and the area of the first upper opening OP1-U defined in the second conductive layer CDL2 may be smaller than the area of the pixel opening OP1-P defined in the first conductive layer CDL1.

As illustrated in FIG. 6A, on a cross section, the second conductive layer CDL2 may have an undercut shape protruding more than the first conductive layer CDL1. On a cross section, the inner side surface of the second conductive layer CDL2 may be closer to the center of the anode AE1 than the inner side surface of the first conductive layer CDL1. That is, a region defined by the inner side surface of the second conductive layer CDL2 may have a smaller width in one direction than a region defined by the inner side surface of the first conductive layer CDL1. In the present disclosure, in the bank layer CPW, a protruding portion of the second conductive layer CDL2 closer to the center of the anode AE1 than the inner side surface of the first conductive layer CDL1 may be defined as a tip portion.

According to one or more embodiments of the present disclosure, the area defined by the inner side surface of the first conductive layer CDL1 on a plane may be greater than the area of the first light-emitting opening OP1-E defined in the pixel defining film ISL, and the first conductive layer CDL1 may expose a portion of the upper surface of the pixel defining film ISL.

The thickness of the first conductive layer CDL1 may be, for example, about 4000 angstroms to about 7000 angstroms. The thickness of the second conductive layer CDL2 may be smaller than that of the first conductive layer CDL1. For example, the thickness of the second conductive layer CDL2 may be about 500 angstroms to about 1000 angstroms.

FIG. 6A illustrates, as an example, that the side surface of the bank layer CPW has a tapered shape with respect to the upper surface of the pixel defining film ISL, but the present disclosure is not limited thereto. For example, the bank layer CPW may have a vertically extending sidewall or have a reverse-tapered shape.

The light-emitting pattern EP1 may be disposed on the anode AE1. The light-emitting pattern EP1 may include a light-emitting layer including a light-emitting material. The light-emitting pattern EP1 may further include a hole injection layer and a hole transport layer, which are disposed between the anode AE1 and the light-emitting layer, and may further include an electron transport layer and an electron injection layer which are disposed on the light-emitting layer. The light-emitting pattern EP1 may also be referred to as an ‘organic layer’ or an ‘intermediate layer’.

The light-emitting pattern EP1 may be patterned by the tip structure defined in the bank layer CPW. The light-emitting pattern EP1 may be disposed inside the sacrificial opening OP1-L, the light-emitting opening OP1-E, and the pixel opening OP1-P. The light-emitting pattern EP1 may cover a portion of the upper surface of the pixel defining film ISL exposed through the pixel opening OP1-P.

The cathode CE1 may be disposed on the light-emitting pattern EP1. The cathode CE1 may be patterned by the tip structure defined in the bank layer CPW. The cathode CE1 may come in contact with the inner side surface of the first conductive layer CDL1 of the bank layer CPW.

The bank layer CPW may receive the second driving voltage ELVSS (see FIG. 4), and accordingly, the cathode CE1 may receive the second driving voltage ELVSS (see FIG. 4) as the cathode CE1 is electrically connected to the bank layer CPW.

According to one or more embodiments of the present disclosure, the light-emitting element ED1 may further include a capping pattern CP1 (e.g., a first capping pattern CP1). The capping pattern CP1 may be disposed in the pixel opening OP1-P and may be disposed on the cathode CE1. The capping pattern CP1 may be patterned by the tip portion formed in the bank layer CPW.

FIG. 6A illustrates, as an example, that the capping pattern CP1 does not come in contact with the inner side surface of the bank layer CPW, but the present disclosure is not limited thereto. For example, the capping pattern CP1 may be formed to be in contact with the inner side surface of the bank layer CPW. In one or more embodiments, the capping pattern CP1 may be omitted.

The display panel DP further includes a thin film encapsulation layer TFE. The thin film encapsulation layer TFE may be disposed on the display element layer DP-OLED. The thin film encapsulation layer TFE includes a lower encapsulation pattern LIP1. The thin film encapsulation layer TFE may further include an organic encapsulation film OL and an upper inorganic encapsulation film UIL.

A portion of the lower encapsulation pattern LIP1 may be disposed to correspond to the pixel opening OP1-P. The lower encapsulation pattern LIP1 may be disposed on the cathode CE1 and the capping pattern CP1 of the light-emitting element ED1, cover the cathode CE1 and the capping pattern CP1, and may be partially disposed inside the pixel opening OP1-P. A portion of the lower encapsulation pattern LIP1 is disposed on the bank layer CPW.

In one or more embodiments, the lower encapsulation pattern LIP1 may be disposed directly on the cathode CE1. According to one or more embodiments, the lower encapsulation pattern LIP1 may cover the inner side surface of the first conductive layer CDL1 and the inner side surface of the second conductive layer CDL2. A portion of the lower encapsulation pattern LIP1 disposed on the bank layer CPW may be disposed to be spaced from the upper surface of the bank layer CPW at a suitable distance (e.g., a predetermined distance), and a suitable separation portion (e.g., a predetermined separation portion) SS1 may be defined between the lower encapsulation pattern LIP1 and the bank layer CPW. The separation portion SS1 may be formed by removing a preliminary dummy pattern layer formed on the bank layer CPW together in a process of removing a photoresist pattern, which will be described later.

The lower encapsulation pattern LIP1 includes a first lower encapsulation pattern LIP-11 and a second lower encapsulation pattern LIP-21. The first lower encapsulation pattern LIP-11 is disposed on the cathode CE1 and the capping pattern CP1, and the second lower encapsulation pattern LIP-21 is disposed on the first lower encapsulation pattern LIP-11. The first lower encapsulation pattern LIP-11 may be directly disposed on the cathode CE1 or on the capping pattern CP1, and the second lower encapsulation pattern LIP-21 may be directly disposed on the first lower encapsulation pattern LIP-11.

A portion of the first lower encapsulation pattern LIP-11 may be disposed on the bank layer CPW. In one or more embodiments, the first lower encapsulation pattern LIP-11 may be disposed to be spaced from the upper surface of the bank layer CPW at a suitable distance (e.g., a predetermined distance), and a suitable separation portion (e.g., a predetermined separation portion) SS1 may be defined between the first lower encapsulation pattern LIP-11 and the bank layer CPW.

The first lower encapsulation pattern LIP-11 and the second lower encapsulation pattern LIP-21 include different materials. The first lower encapsulation pattern LIP-11 and the second lower encapsulation pattern LIP-21 may include materials having different etch rates. The first lower encapsulation pattern LIP-11 and the second lower encapsulation pattern LIP-21 may include materials having different etch rates in an etching process by using a photoresist pattern, which will be described later, as a mask. The second lower encapsulation pattern LIP-21 may include a material having a lower etch rate than that of the first lower encapsulation pattern LIP-11.

In one or more embodiments of the present disclosure, the first lower encapsulation pattern LIP-11 includes a first material. The first material may include an inorganic material such as silicon nitride, silicon oxynitride, silicon oxide, titanium oxide, and/or aluminum oxide. The second lower encapsulation pattern LIP-21 includes a second material different from the first material included in the first lower encapsulation pattern LIP-11. In one or more embodiments of the present disclosure, the second material may include silicon oxynitride (SiON), indium zinc oxide (IZO), and/or indium gallium zinc oxide (IGZO). Alternatively, the second material may include a metallic material. As the first lower encapsulation pattern LIP-11 and the second lower encapsulation pattern LIP-21 respectively include materials having different etching rates, the second lower encapsulation pattern LIP-21 may include a tip portion TP1 (see FIG. 6B), which will be described later.

The second lower encapsulation pattern LIP-21 may have a smaller thickness than the first lower encapsulation pattern LIP-11. The second lower encapsulation pattern LIP-21 may be provided in the form of a thin film having a smaller thickness than the first lower encapsulation pattern LIP-11.

The organic encapsulation film OL may cover an inorganic layer and/or the lower encapsulation pattern LIP1 and provide a flat upper surface. The upper inorganic encapsulation film UIL may be disposed on the organic encapsulation film OL.

The lower encapsulation pattern LIP1 and the upper inorganic encapsulation film UIL may protect the display element layer DP-OLED from moisture/oxygen, and the organic encapsulation film OL may protect the display element layer DP-OLED from foreign substances such as dust particles. The upper inorganic encapsulation film UIL may include silicon nitride, silicon oxynitride, silicon oxide, titanium oxide, aluminum oxide, and/or the like, but the present disclosure is not particularly limited thereto. The organic encapsulation film OL may include an acrylic-based compound, an epoxy-based compound, or the like. The organic encapsulation film OL may include a photopolymerizable organic material, but is not particularly limited thereto.

FIGS. 6B and 6C are cross-sectional views of the display panel according to one or more embodiments of the present disclosure. FIG. 6B is a cross-sectional view taken along the line II-II′ of FIG. 5. FIG. 6C is a cross-sectional view taken along the line III-III′ of FIG. 5. FIG. 6B is an enlarged view of one first light-emitting region PXA-R, one second light-emitting region PXA-G, and one third light-emitting region PXA-B. The description of the light-emitting region PXA-R with reference to FIG. 6A will be equally applied to each of the first to third light-emitting regions PXA-R, PXA-G, and PXA-B. FIG. 6C illustrates in more detail the arrangement relationship of lower encapsulation patterns LIP1 and LIP2 between the first and second light-emitting regions PXA-R and PXA-G adjacent to each other.

Referring to FIGS. 6A to 6C, the display panel DP according to this embodiment may include a base layer BL, a circuit element layer DP-CL, a display element layer DP-OLED, and a thin film encapsulation layer TFE. The display element layer DP-OLED may include light-emitting elements ED1, ED2, and ED3, sacrificial patterns SP1, SP2, and SP3, a pixel defining film ISL, and a bank layer CPW. The display element layer DP-OLED may further include dummy patterns DMP. The thin film encapsulation layer TFE may include lower encapsulation patterns LIP1, LIP2, and LIP3, an organic encapsulation film OL, and an upper inorganic encapsulation film UIL.

The light-emitting elements ED1, ED2, and ED3 may include a first light-emitting element ED1, a second light-emitting element ED2, and a third light-emitting element ED3. The first light-emitting element ED1 may include the first anode AE1, the first light-emitting pattern EP1, the first cathode CE1, and the first capping pattern CP1. The second light-emitting element ED2 may include a second anode AE2, a second light-emitting pattern EP2, a second cathode CE2, and a second capping pattern CP2. The third light-emitting element ED3 may include a third anode AE3, a third light-emitting pattern EP3, a third cathode CE3, and a third capping pattern CP3. The first to third anodes AE1, AE2, and AE3 may be provided as a plurality of patterns. In one or more embodiments of the present disclosure, the first light-emitting pattern EP1 may provide red light, the second light-emitting pattern EP2 may provide green light, and the third light-emitting pattern EP3 may provide blue light.

The lower encapsulation patterns LIP1, LIP2, and LIP3 are disposed on the light-emitting elements ED1, ED2, and ED3. The lower encapsulation patterns LIP1, LIP2, and LIP3 are respectively disposed on the cathodes CE1, CE2, and CE3 and the capping patterns CP1, CP2, and CP3. The lower encapsulation patterns LIP1, LIP2, and LIP3 respectively include first lower encapsulation patterns LIP-11, LIP-12, and LIP-13 disposed on the cathodes CE1, CE2, and CE3 and the capping patterns CP1, CP2, and CP3, and second lower encapsulation patterns LIP-21, LIP-22, and LIP-23 disposed on the first lower encapsulation patterns LIP-11, LIP-12, and LIP-13. The first lower encapsulation patterns LIP-11, LIP-12, and LIP-13 and the second lower encapsulation patterns LIP-21, LIP-22, and LIP-23 include different materials. As the first lower encapsulation patterns LIP-11, LIP-12, and LIP-13 and the second lower encapsulation patterns LIP-21, LIP-22, and LIP-23 include different materials, the second lower encapsulation patterns LIP-21, LIP-22, and LIP-23 may include tip portions TP1, TP2, and TP3 having a protruding shape.

First to third light-emitting openings OP1-E, OP2-E, and OP3-E may be defined in the pixel defining film ISL. The first light-emitting opening OP1-E may expose at least a portion of the first anode AE1. The first light-emitting region PXA-R may be defined as a region exposed by the first light-emitting opening OP1-E from among the upper surface of the first anode AE1. The second light-emitting opening OP2-E may expose at least a portion of the second anode AE2. The second light-emitting region PXA-G may be defined as a region exposed by the second light-emitting opening OP2-E from among the upper surface of the second anode AE2.

The third light-emitting opening OP3-E may expose at least a portion of the third anode AE3. The third light-emitting region PXA-B may be defined as a region exposed by the third light-emitting opening OP3-E from among the upper surface of the third anode AE3.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be respectively disposed on the upper surfaces of the first to third anodes AE1, AE2, and AE3. First to third sacrificial openings respectively corresponding to the first to third light-emitting openings OP1-E, OP2-E, and OP3-E may be defined in the first to third sacrificial patterns SP1, SP2, and SP3.

In this embodiment, first to third pixel openings OP1-P, OP2-P, and OP3-P respectively corresponding to the first to third light-emitting openings OP1-E, OP2-E, and OP3-E may be defined in the bank layer CPW.

The first light-emitting pattern EP1 and the first cathode CE1 may be disposed in the first pixel opening OP1-P, the second light-emitting pattern EP2 and the second cathode CE2 may be disposed in the second pixel opening OP2-P, and the third light-emitting pattern EP3 and the third cathode CE3 may be disposed in the third pixel opening OP3-P. The first to third cathodes CE1, CE2, and CE3 may respectively come in contact with the inner side surfaces of the first conductive layer CDL1.

In this embodiment, because the first to third cathodes CE1, CE2, and CE3 are physically separated by the second conductive layer CDL2 that forms a tip structure, are respectively formed in the light-emitting openings OP1-E, OP2-E, and OP3-E, and come in contact with the first conductive layer CDL1, the first to third cathodes CE1, CE2, and CE3 may be electrically connected to each other and receive a common voltage. The first conductive layer CDL1 in contact with each of the first to third cathodes CE1, CE2, and CE3 has a relatively high electrical conductivity, compared to the second conductive layer CDL2, and therefore, it is possible to reduce contact resistance with the first to third cathodes CE1, CE2, and CE3. Accordingly, a common cathode voltage may be uniformly provided to the light-emitting regions PXA-R, PXA-G, and PXA-B.

According to this inventive concept, the plurality of light-emitting patterns EP1, EP2, and EP3 may be patterned and deposited in pixel units by the tip structure defined in the bank layer CPW. That is, the plurality of light-emitting patterns EP1, EP2, and EP3 are commonly formed by using an open mask, but they can be easily divided into the pixel units by the bank layer CPW.

On the other hand, when the plurality of light-emitting patterns EP1, EP2, and EP3 are patterned by using a fine metal mask, a support spacer protruding from a conductive bank layer should be provided to support the fine metal mask. In addition, because the fine metal mask is spaced from a base surface, on which patterning is performed, by as much as the height of the bank layer and the spacer, there may be a limitation in realizing high resolution. In addition, as the fine metal mask is in contact with the spacer, foreign substances may remain on the spacer after a process of patterning the plurality of light-emitting patterns EP1, EP2, and EP3, or the spacer may be damaged by being stabbed by the fine metal mask. Accordingly, a defective display panel may be formed.

According to this embodiment, by including the bank layer CPW, physical separation between the light-emitting elements ED1, ED2, and ED3 may be easily achieved. Accordingly, it is possible not only to prevent a current leakage or a driving error between adjacent light-emitting regions PXA-R, PXA-G, and PXA-B, but also to drive each of the light-emitting elements ED1, ED2, and ED3 independently.

In particular, by patterning the plurality of light-emitting patterns EP1, EP2, and EP3 without a mask in contact with internal components in the display region DA (see FIG. 1B), a defect rate may be reduced, thus making it possible to provide the display panel DP having improved process reliability. Because patterning is possible even when a separate support spacer protruding from the bank layer CPW is not provided, the areas of the light-emitting regions PXA-R, PXA-G, and PXA-B may be reduced or minimized and therefore, it is possible to provide the display panel DP capable of easily achieving high resolution.

In addition, in manufacturing the display panel DP having a large area, a process cost may be reduced by omitting the manufacture of a mask having a large area, and it is possible to provide the display panel DP having improved process reliability by not being affected by a defect which may occur in a large-area mask.

The capping patterns CP1, CP2, and CP3 may include the first capping pattern CP1, the second capping pattern CP2, and the third capping pattern CP3. The first to third capping patterns CP1, CP2, CP3 may be respectively disposed on the first to third cathodes CE1, CE2, and CE3 in the first to third bank layer openings OP1-P, OP2-P, and OP3-P.

The display panel according to one or more embodiments of the present disclosure may further include dummy patterns DMP. The dummy patterns DMP may be disposed on a portion of the upper portion of the bank layer CPW disposed in the peripheral region NPXA between adjacent light-emitting regions PXA-R, PXA-G, and PXA-B. In one or more embodiments, some of the dummy patterns DMP may be disposed adjacent to the second light-emitting regions PXA-G. Some of the dummy patterns DMP may be disposed adjacent to the third light-emitting regions PXA-B. Each of the dummy patterns DMP may include a first layer dummy pattern D1, a second layer dummy pattern D2, and a third layer dummy pattern D3. The first to third layer dummy patterns D1, D2, and D3 may be sequentially stacked along the third direction DR3 on the upper surface of the second conductive layer CDL2 of the bank layer CPW.

The dummy patterns DMP may include the first to third layer dummy patterns D1, D2, and D3 disposed to be around (e.g., to surround) at least a portion of the second light-emitting regions PXA-G or the third light-emitting regions PXA-B disposed adjacent thereto on a plane.

The first layer dummy pattern D1 may include an organic material. The first layer dummy pattern D1 may include the same material as the second light-emitting pattern EP2 or the third light-emitting pattern EP3 and may be formed through the same process as the second light-emitting pattern EP2 or the third light-emitting pattern EP3. The first layer dummy pattern D1 may be formed separately from the second or third light-emitting pattern EP2 or EP3 by the undercut shape of the bank layer CPW.

The second layer dummy pattern D2 may include a conductive material. The second layer dummy pattern D2 may include the same material as the second cathode CE2 or the third cathode CE3 and may be formed through the same process as the second cathode CE2 or the third cathode CE3. The second layer dummy pattern D2 may be formed separately from the second cathode CE2 or the third cathode CE3 by the undercut shape of the bank layer CPW.

The third layer dummy pattern D3 may include the same material as the second capping pattern CP2 or the third capping pattern CP3 and may be formed through the same process as the second capping pattern CP2 or the third capping pattern CP3. The third layer dummy pattern D3 may be formed separately from the second capping pattern CP2 or the third capping pattern CP3 by the undercut shape of the bank layer CPW.

The thin film encapsulation layer TFE may include lower encapsulation patterns LIP1, LIP2, and LIP3, an organic encapsulation film OL, and an upper inorganic encapsulation film UIL.

In this embodiment, the lower encapsulation patterns LIP1, LIP2, and LIP3 may include a first pixel encapsulation pattern LIP1, a second pixel encapsulation pattern LIP2, and a third pixel encapsulation pattern LIP3. The lower encapsulation patterns LIP1, LIP2, and LIP3 may respectively correspond to the first to third light-emitting openings OP1-E, OP2-E, and OP3-E. The lower encapsulation patterns LIP1, LIP2, and LIP3 may be disposed to respectively correspond to the first to third light-emitting elements ED1, ED2, and ED3.

The lower encapsulation patterns LIP1, LIP2, and LIP3 may be provided in the form of patterns that are spaced from each other on a plane. The lower encapsulation patterns LIP1, LIP2, and LIP3 may be directly disposed on the first to third cathodes CE1, CE2, and CE3 or the first to third and the capping patterns CP1, CP2, and CP3, respectively.

The first pixel encapsulation pattern LIP1 may cover the first light-emitting element ED1, and a portion of the first pixel encapsulation pattern LIP1 may be disposed inside the first pixel opening OP1-P. The first pixel encapsulation pattern LIP1 may be directly disposed on the first cathode CE1 or the first capping pattern CP1. The first pixel encapsulation pattern LIP1 may be disposed to be spaced from the upper surface of the bank layer CPW at a suitable distance (e.g., a predetermined distance), and a suitable first separation portion (e.g., a predetermined first separation portion) SS1 may be defined between the first pixel encapsulation pattern LIP1 and the bank layer CPW. The first separation portion SS1 may be formed by removing a preliminary dummy pattern layer formed on the bank layer CPW together in a photoresist pattern removal process which will be described later.

The first pixel encapsulation pattern LIP1 includes a (1-1)-th lower encapsulation pattern LIP-11 and a (2-1)-th lower encapsulation pattern LIP-21. The (1-1)-th lower encapsulation pattern LIP-11 is disposed on the first cathode CE1 and the first capping pattern CP1, and the (2-1)-th lower encapsulation pattern LIP-21 is disposed on the (1-1)-th lower encapsulation pattern LIP-11. The (1-1)-th lower encapsulation pattern LIP-11 may be directly disposed on the first cathode CE1 or the first capping pattern CP1, and the (2-1)-th lower encapsulation pattern LIP-21 may be directly disposed on the (1-1)-th lower encapsulation pattern LIP-11.

A portion of the (1-1)-th lower encapsulation pattern LIP-11 may be disposed above the bank layer CPW. In one or more embodiments, the (1-1)-th lower encapsulation pattern LIP-11 may be disposed to be spaced from the upper surface of the bank layer CPW at a suitable distance (e.g., a predetermined distance), and a suitable first separation portion (e.g., a predetermined first separation portion) SS1 may be defined between the (1-1)-th lower encapsulation pattern LIP-11 and the bank layer CPW.

The (1-1)-th lower encapsulation pattern LIP-11 and the (2-1)-th lower encapsulation pattern LIP-21 include different materials. The (1-1)-th lower encapsulation pattern LIP-11 and the (2-1)-th lower encapsulation pattern LIP-21 may include materials having different etch rates. The (1-1)-th lower encapsulation pattern LIP-11 and the (2-1)-th lower encapsulation pattern LIP-21 may include materials having different etch rates in an etching process which uses a photoresist pattern as a mask, which will be described later. The (2-1)-th lower encapsulation pattern LIP-21 may include a material having a lower etch rate than the (1-1)-th lower encapsulation pattern LIP-11.

In one or more embodiments, the (1-1)-th lower encapsulation pattern LIP-11 includes a first material. The first material may include an inorganic material such as silicon nitride, silicon oxynitride, silicon oxide, titanium oxide, and/or aluminum oxide. The (2-1)-th lower encapsulation pattern LIP-21 includes a second material different from the first material included in the (1-1)-th lower encapsulation pattern LIP-11. In one or more embodiments, the second material may include silicon oxynitride (SiON), indium zinc oxide (IZO), and/or indium gallium zinc oxide (IGZO). Alternatively, the second material may include a metallic material.

The (2-1)-th lower encapsulation pattern LIP-21 may have a smaller thickness than the (1-1)-th lower encapsulation pattern LIP-11. The (2-1)-th lower encapsulation pattern LIP-21 may be provided in the form of a thin film having a smaller thickness than the (1-1)-th lower encapsulation pattern LIP-11.

The (2-1)-th lower encapsulation pattern LIP-21 includes a first tip portion TP1 protruding in a direction away from the (1-1)-th lower encapsulation pattern LIP-11. The first tip portion TP1 included in the (2-1)-th lower encapsulation pattern LIP-21 may have a shape that protrudes from an end of the (1-1)-th lower encapsulation pattern LIP-11. The (2-1)-th lower encapsulation pattern LIP-21 may include a second material having a lower etch rate than the material of the (1-1)-th lower encapsulation pattern LIP-11 and include the first tip portion TP1 having a shape that protrudes from the end of the (1-1)-th lower encapsulation pattern LIP-11.

The second pixel encapsulation pattern LIP2 may cover the second light-emitting element ED2, and a portion thereof may be disposed inside the second pixel opening OP2-P. The second pixel encapsulation pattern LIP2 may be directly disposed on the second cathode CE2 and the second capping pattern CP2. The second pixel encapsulation pattern LIP2 may be disposed to be spaced from the upper surface of the bank layer CPW at a suitable distance (e.g., a predetermined distance), and a suitable second separation portion (e.g., a predetermined second separation portion) SS2 may be defined between the second pixel encapsulation pattern LIP2 and the bank layer CPW. The second separation portion SS2 may be formed by removing a preliminary dummy pattern layer formed on the bank layer CPW together in a photoresist pattern removal process which will be described later.

The second pixel encapsulation pattern LIP2 includes a (1-2)-th lower encapsulation pattern LIP-12 and a (2-2)-th lower encapsulation pattern LIP-22. The (1-2)-th lower encapsulation pattern LIP-12 is disposed on the second cathode CE2 and the second capping pattern CP2, and the second lower encapsulation pattern LIP-22 is disposed on the (1-2)-th lower encapsulation pattern LIP-12. The (1-2)-th lower encapsulation pattern LIP-12 may be directly disposed on the second cathode CE2 or the second capping pattern CP2, and the (2-2)-th lower encapsulation pattern LIP-22 may be disposed directly on the (1-2)-th lower encapsulation pattern LIP-12.

A portion of the (1-2)-th lower encapsulation pattern LIP-12 may be disposed above the bank layer CPW. In one or more embodiments, the (1-2)-th lower encapsulation pattern LIP-12 may be disposed to be spaced from the upper surface of the bank layer CPW at a suitable distance (e.g., a predetermined distance), and a suitable second separation portion (e.g., a predetermined second separation portion) SS2 may be defined between the (1-2)-th lower encapsulation pattern LIP-12 and the bank layer CPW.

Some of the dummy patterns DMP described above may be disposed between the (1-2)-th lower encapsulation pattern LIP-12 and the bank layer CPW. The dummy patterns DMP may be disposed on the upper surface of the second conductive layer CDL2, and the (1-2)-th lower encapsulation pattern LIP-12 may be disposed on the third layer dummy pattern D3 from among the dummy patterns DMP.

The (1-2)-th lower encapsulation pattern LIP-12 and the (2-2)-th lower encapsulation pattern LIP-22 include different materials. The (1-2)-th lower encapsulation pattern LIP-12 and the (2-2)-th lower encapsulation pattern LIP-22 may include materials having different etch rates. The (1-2)-th lower encapsulation pattern LIP-12 and the (2-2)-th lower encapsulation pattern LIP-22 may include materials having different etch rates in an etching process which uses a photoresist pattern as a mask, which will be described later. The (2-2)-th lower encapsulation pattern LIP-22 may include a material having a lower etch rate than that of the (1-2)-th lower encapsulation pattern LIP-12.

In one or more embodiments, the (1-2)-th lower encapsulation pattern LIP-12 includes a first material. The first material may include an inorganic material such as silicon nitride, silicon oxy nitride, silicon oxide, titanium oxide, and/or aluminum oxide. The (2-2)-th lower encapsulation pattern LIP-22 includes a second material different from the first material included in the (1-2)-th lower encapsulation pattern LIP-12. In one or more embodiments, the second material may include silicon oxynitride (SiON), indium zinc oxide (IZO), and/or indium gallium zinc oxide (IGZO). Alternatively, the second material may include a metallic material.

The (2-2)-th lower encapsulation pattern LIP-22 may have a smaller thickness than the (1-2)-th lower encapsulation pattern LIP-12. The (2-2)-th lower encapsulation pattern LIP-22 may be provided in the form of a thin film having a smaller thickness than the (1-2)-th lower encapsulation pattern LIP-12.

The (2-2)-th lower encapsulation pattern LIP-22 includes a second tip portion TP2 protruding in a direction away from the (1-2)-th lower encapsulation pattern LIP-12. The second tip portion TP2 included in the 2-2 lower encapsulation pattern LIP-22 may have a shape that protrudes from an end of the (1-2)-th lower encapsulation pattern LIP-12. The (2-2)-th lower encapsulation pattern LIP-22 may include a second material having a lower etch rate than the material of the (1-2)-th lower encapsulation pattern LIP-12 and may include the second tip portion TP2 having a shape that protrudes from the end of the (1-2)-th lower encapsulation pattern LIP-12.

At least a portion of the second pixel encapsulation pattern LIP2 may be disposed above the first pixel encapsulation pattern LIP1. In one or more embodiments, a portion of each of the (1-2)-th lower encapsulation pattern LIP-12 and the (2-2)-th lower encapsulation pattern LIP-22 included in the second pixel encapsulation pattern LIP2 may be disposed above the first pixel encapsulation pattern LIP1. As illustrated in FIG. 6B, a portion of each of the (1-2)-th lower encapsulation pattern LIP-12 and the (2-2)-th lower encapsulation pattern LIP-22 may be disposed above the (1-1)-th lower encapsulation pattern LIP-11 and the (2-1)-th lower encapsulation pattern LIP-21 in the peripheral region NPXA disposed between the first light-emitting region PXA-R and the second light-emitting region PXA-G. In one or more embodiments, the (2-1)-th lower encapsulation pattern LIP-21 and the (1-2)-th lower encapsulation pattern LIP-12 disposed above the (2-1)-th lower encapsulation pattern LIP-21 may be disposed to be spaced from each other at a suitable distance (e.g., a predetermined distance). A first gap GP1 may be defined between the (2-1)-th lower encapsulation pattern LIP-21 and the (1-2)-th lower encapsulation pattern LIP-12.

A portion of the (1-2)-th lower encapsulation pattern LIP-12 may come in contact with the (1-1)-th lower encapsulation pattern LIP-11. A portion of the (1-2)-th lower encapsulation pattern LIP-12 may be disposed below the first tip portion TP1 defined in the (2-1)-th lower encapsulation pattern LIP-21 and come in contact with the (2-1)-th lower encapsulation pattern LIP-21.

Referring to FIG. 6C, the (1-2)-th lower encapsulation pattern LIP-12 may include a first portion P1 disposed above the bank layer CPW. The first portion P1 may include a (1-1)-th portion P1-1, a (1-2)-th portion P1-2, and a (1-3)-th portion P1-3 disposed above the bank layer CPW. In one or more embodiments, for the convenience of explanation, the (1-1) portion P1-1, the (1-2)-th portion P1-2, and the (1-3)-th portion P1-3 are described as separate components, but the (1-1) portion P1-1, the (1-2)-th portion P1-2, and the (1-3)-th portion P1-3 may not be components separated from each other with interfaces interposed therebetween and may have an integral shape.

The (1-1)-th portion P1-1 may be disposed on the dummy pattern DMP and may not overlap the (2-1)-th lower encapsulation pattern LIP-21. The (1-2)-th portion P1-2 may be disposed on the dummy pattern DMP and may be disposed below the first tip portion TP1 defined in the (2-1)-th lower encapsulation pattern LIP-21. The (1-2) portion P1-2 may be disposed below the (2-1)-th lower encapsulation pattern LIP-21 and may be in contact with the (1-1)-th lower encapsulation pattern LIP-11.

In one or more embodiments, an air gap AG may be defined in the (1-2)-th portion P1-2. The air gap AG may be formed in the (1-2)-th portion P1-2, and the air gap AG may be formed by the first tip portion TP1 in the process of forming the (1-2)-th lower encapsulation pattern LIP-12. Although a suitable sir gap (e.g., a predetermined air gap) AG is defined in the (1-2)-th portion P1-2, a portion of the (1-2)-th portion P1-2 may come in contact with the (1-1)-th lower encapsulation pattern LIP-11 in the form of a thin film.

The (1-3)-th portion P1-3 may be disposed above the (2-1)-th lower encapsulation pattern LIP-21. The (1-3)-th portion P1-3 may be disposed to be spaced from the upper surface of the (2-1)-th lower encapsulation pattern LIP-21 at a suitable distance (e.g., a predetermined distance). A first gap GP1 may be defined between the (1-3)-th portion P1-3 and the (2-1)-th lower encapsulation pattern LIP-21.

The third pixel encapsulation pattern LIP3 may cover the third light-emitting element ED3, and a portion thereof may be disposed inside the third pixel opening OP3-P. The third pixel encapsulation pattern LIP3 may be directly disposed on the third cathode CE3 or the third capping pattern CP3. The third pixel encapsulation pattern LIP3 may be disposed to be spaced from the upper surface of the bank layer CPW at a suitable distance (e.g., a predetermined distance), and a suitable third separation portion (e.g., a predetermined third separation portion) SS3 may be defined between the third pixel encapsulation pattern LIP3 and the bank layer CPW. The third separation portion SS3 may be formed by removing a preliminary dummy pattern layer formed on the bank layer CPW together in a photoresist pattern removal process which will be described later.

The third pixel encapsulation pattern LIP3 includes a (1-3)-th lower encapsulation pattern LIP-13 and a (2-3)-th lower encapsulation pattern LIP-23. The (1-3)-th lower encapsulation pattern LIP-13 is disposed on the third cathode CE3 and the third capping pattern CP3, and the (2-3)-th lower encapsulation pattern LIP-23 is disposed on the (1-3)-th lower encapsulation pattern LIP-13. The (1-3)-th lower encapsulation pattern LIP-13 may be directly disposed on the third cathode CE3 or the third capping pattern CP3, and the (2-3)-th lower encapsulation pattern LIP-23 may be directly disposed on the (1-3)-th lower encapsulation pattern LIP-13.

A portion of the (1-3)-th lower encapsulation pattern LIP-13 may be disposed on the bank layer CPW. In one or more embodiments, the (1-3)-th lower encapsulation pattern LIP-13 may be disposed to be spaced from the upper surface of the bank layer CPW at a suitable distance (e.g., a predetermined distance), and a suitable third separation portion (e.g., a predetermined third separation portion) SS3 may be defined between the (1-3)-th lower encapsulation pattern LIP-13 and the bank layer CPW.

Some of the dummy patterns DMP described above may be disposed between the (1-3)-th lower encapsulation pattern LIP-13 and the bank layer CPW. The dummy patterns DMP may be disposed on the upper surface of the second conductive layer CDL2, and the (1-3)-th lower encapsulation patterns LIP-13 may be disposed on the third layer dummy pattern D3 from among the dummy patterns DMP.

The (1-3)-th lower encapsulation pattern LIP-13 and the (2-3)-th lower encapsulation pattern LIP-23 include different materials. The (1-3)-th lower encapsulation pattern LIP-13 and the (2-3)-th lower encapsulation pattern LIP-23 may include materials having different etch rates. The (1-3)-th lower encapsulation pattern LIP-13 and the (2-3)-th lower encapsulation pattern LIP-23 may include materials having different etch rates in an etching process which uses a photoresist pattern as a mask, which will be described later. The (2-3)-th lower encapsulation pattern LIP-23 may include a material having a lower etch rate than that of the (1-3)-th lower encapsulation pattern LIP-13.

In one or more embodiments, the (1-3)-th lower encapsulation pattern LIP-13 includes a first material. The first material may include an inorganic material such as silicon nitride, silicon oxynitride, silicon oxide, titanium oxide, and/or aluminum oxide. The (2-3)-th lower encapsulation pattern LIP-23 includes a second material different from the first material included in the (1-3)-th lower encapsulation pattern LIP-13. In one or more embodiments, the second material may include silicon oxynitride (SiON), indium zinc oxide (IZO), and/or indium gallium zinc oxide (IGZO). Alternatively, the second material may include a metallic material.

The (2-3)-th lower encapsulation pattern LIP-23 may have a smaller thickness than the (1-3)-th lower encapsulation pattern LIP-13. The (2-3)-th lower encapsulation pattern LIP-23 may be provided in the form of a thin film having a smaller thickness than the (1-3)-th lower encapsulation pattern LIP-13.

The (2-3)-th lower encapsulation pattern LIP-23 includes a third tip portion TP3 protruding in a direction away from the (1-3)-th lower encapsulation pattern LIP-13. The third tip portion TP3 included in the (2-3)-th lower encapsulation pattern LIP-23 may have a shape that protrudes from an end of the (1-3)-th lower encapsulation pattern LIP-13. The (2-3)-th lower encapsulation pattern LIP-23 may include a second material having a lower etch rate than the material of the (1-3)-th lower encapsulation pattern LIP-13 and may include a third tip portion TP3 having a shape that protrudes from the end of the (1-3)-th lower encapsulation pattern LIP-13.

At least a portion of the third pixel encapsulation pattern LIP3 may be disposed above the second pixel encapsulation pattern LIP2. In one or more embodiments, a portion of each of the (1-3)-th lower encapsulation pattern LIP-13 and the (2-3)-th lower encapsulation pattern LIP-23 included in the third pixel encapsulation pattern LIP3 may be disposed above the second pixel encapsulation pattern LIP2. As illustrated in FIG. 6B, a portion of each of the (1-3)-th lower encapsulation pattern LIP-13 and the (2-3)-th lower encapsulation pattern LIP-23 may be disposed above the (1-2)-th lower encapsulation pattern LIP-12 and the 2-2 lower encapsulation pattern LIP-22 in the peripheral region NPXA disposed between the second light-emitting region PXA-G and the third light-emitting region PXA-B. In one or more embodiments, the (2-2)-th lower encapsulation pattern LIP-22 and the (1-3)-th lower encapsulation pattern LIP-13 disposed above the (2-2)-th lower encapsulation pattern LIP-22 may be disposed to be spaced from each other at a suitable distance (e.g., a predetermined distance). A second gap GP2 may be defined between the (2-2)-th lower encapsulation pattern LIP-22 and the (1-3)-th lower encapsulation pattern LIP-13.

A portion of the (1-3)-th lower encapsulation pattern LIP-13 may come in contact with the (1-2)-th lower encapsulation pattern LIP-12. A portion of the (1-3)-th lower encapsulation pattern LIP-13 may be disposed below the second tip portion TP2 defined in the (2-2)-th lower encapsulation pattern LIP-22.

The organic encapsulation film OL may cover the inorganic film and/the first to third lower encapsulation patterns LIP1, LIP2, and LIP3, and provide a flat upper surface. The upper inorganic encapsulation film UIL may be disposed on the organic encapsulation film OL.

The first to third lower encapsulation patterns LIP1, LIP2, and LIP3, the inorganic film, and the upper inorganic encapsulation film UIL may protect the display element layer DP-OLED from moisture/oxygen, and the organic encapsulation film OL may protect the display element layer DP-OLED from foreign substances such as dust particles.

In the display panel DP according to one or more embodiments, the plurality of light-emitting patterns EP1, EP2, and EP3 and the cathodes CE1, CE2, and CE3 are easily divided into pixel units by a tip structure defined by the bank layer CPW, and the display panel DP includes lower encapsulation patterns LIP1, LIP2, and LIP3 patterned above the plurality of light-emitting patterns EP1, EP2, and EP3, respectively. Because the lower encapsulation patterns LIP1, LIP2, and LIP3 respectively include first lower encapsulation patterns LIP-11, LIP-12, and LIP-13 disposed above the cathodes CE1, CE2, and CE3 and the capping patterns CP1, CP2, and CP3, and second lower encapsulation patterns LIP-21, LIP-22, and LIP-23 disposed on the first lower encapsulation patterns LIP-11, LIP-12, and LIP-13, and the first lower encapsulation patterns LIP-11, LIP-12, and LIP-13 and the second lower encapsulation patterns LIP-21, LIP-22, and LIP-23 include different materials, the second lower encapsulation patterns LIP-21, LIP-22, and LIP-23 include tip portions TP1, TP2, and TP3 having a protruding shape.

According to a structure including the tip portions TP1, TP2, and TP3, two adjacent first lower encapsulation patterns LIP-11, LIP-12, and LIP-13 from among the first lower encapsulation patterns LIP-11, LIP-12, and LIP-13 have a structure in which the two adjacent first lower encapsulation patterns LIP-11, LIP-12, and LIP-13 are in contact with each other. For example, as illustrated in FIGS. 6B and 6C, the (1-1)-th lower encapsulation pattern LIP-11 and the (1-2)-th lower encapsulation pattern LIP-12 respectively disposed in adjacent first and second light-emitting regions PXA-R and PXA-G may be in contact with each other. In the display panel according to one or more embodiments, two first lower encapsulation patterns LIP-11, LIP-12, and LIP-13 may have a structure, in which they are in contact with each other, according to the structures of the tip portions TP1, TP2, and TP3 of the second lower encapsulation pattern LIP-21, LIP-22, and LIP-23 disposed above, and therefore, it is possible to form a pixel encapsulation structure with improved durability. More specifically, because the first lower encapsulation patterns LIP-11, LIP-12, and LIP-13 formed through a chemical vapor deposition (CVD) process and the like may be implemented to have structures which have bonding surfaces facing each other, it is possible not only to prevent the light-emitting patterns EP1, EP2, and EP3 from being damaged by external moisture and the like due to an air gap between the lower encapsulation patterns, but also to prevent the lower encapsulation patterns from being lost or lifted in a subsequent process as the bonding strength of the lower encapsulation patterns is improved. Accordingly, the reliability and durability of the display panel DP may be improved.

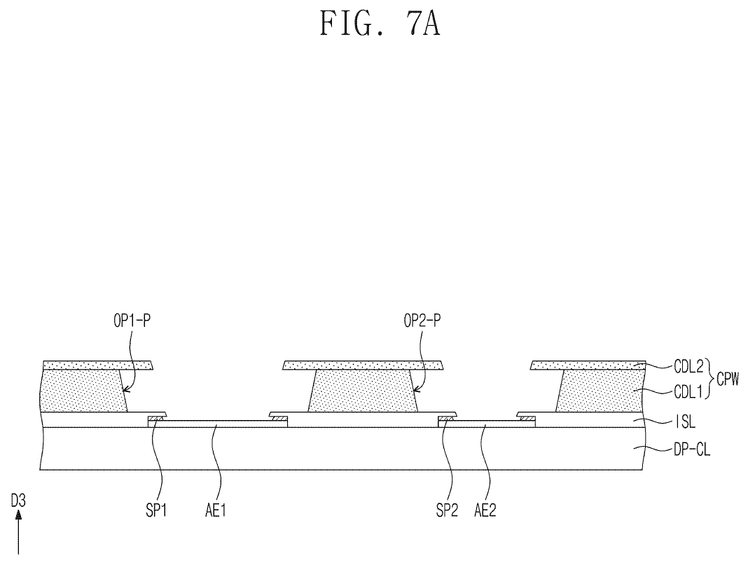

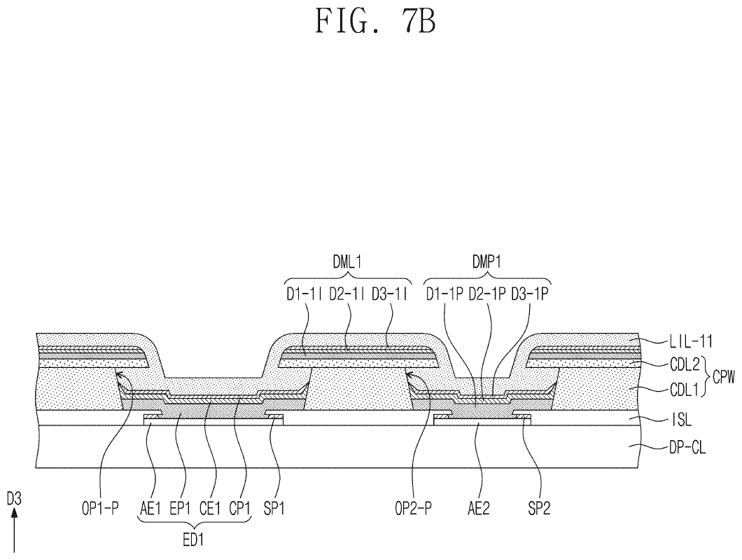

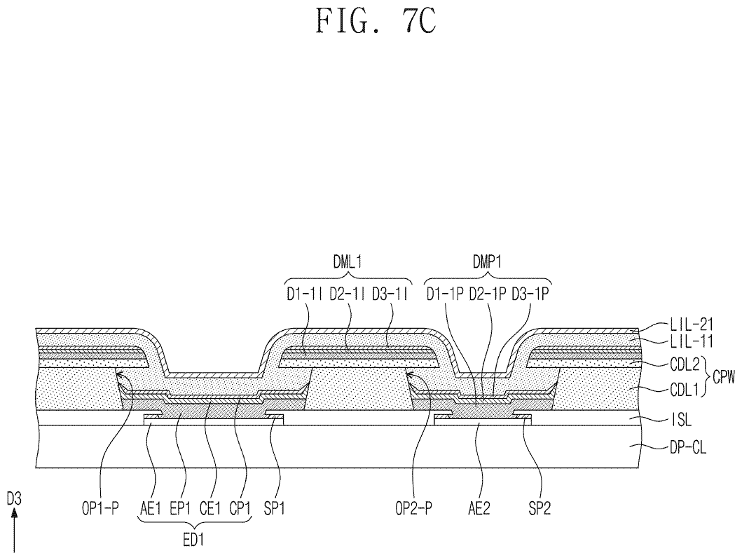

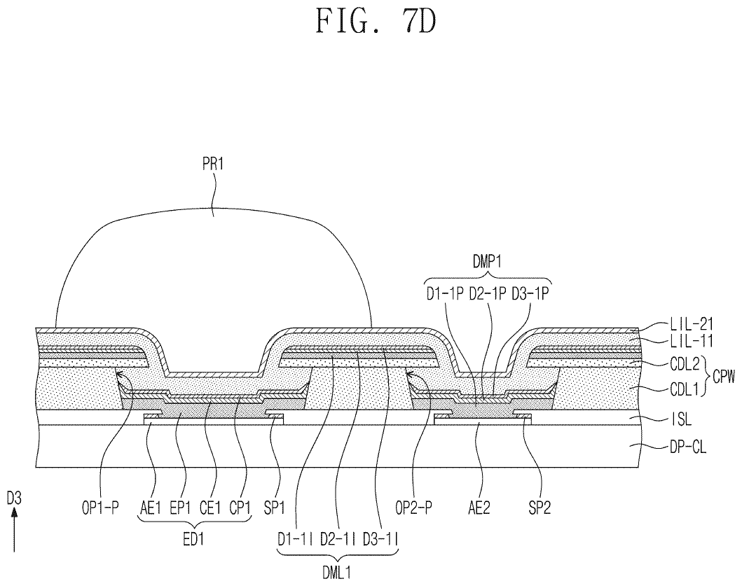

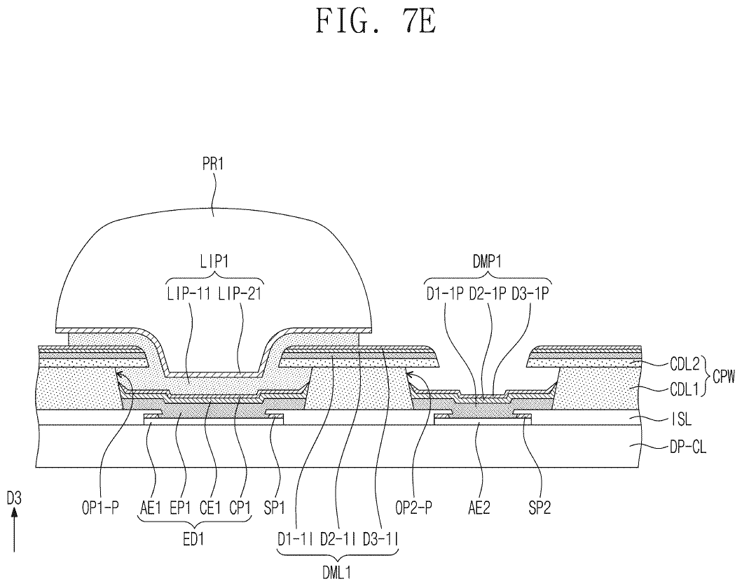

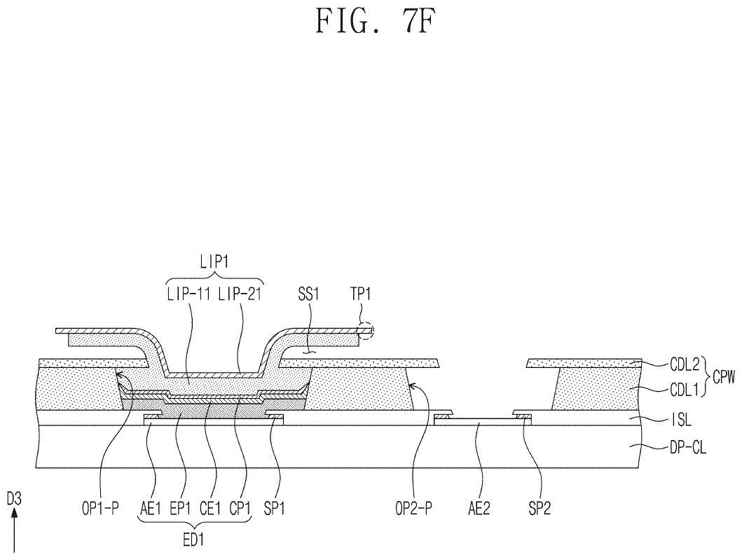

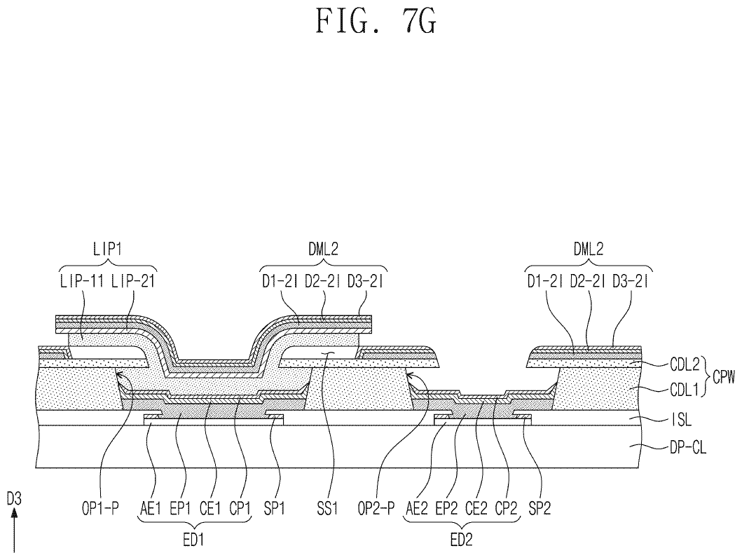

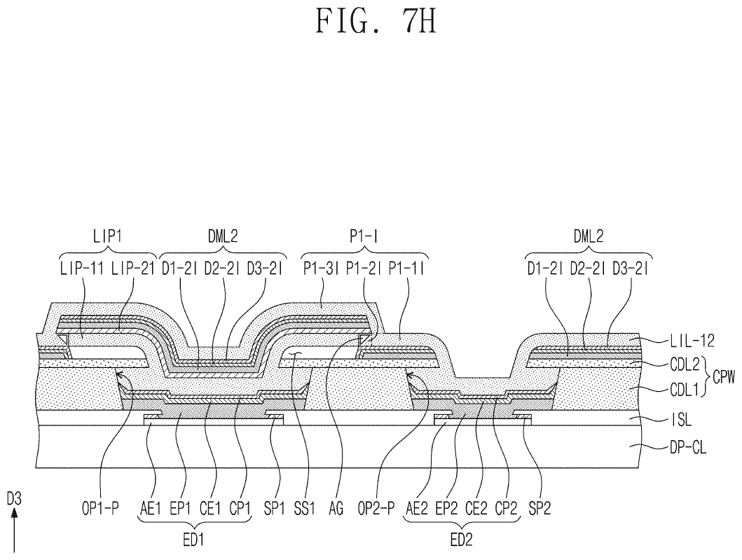

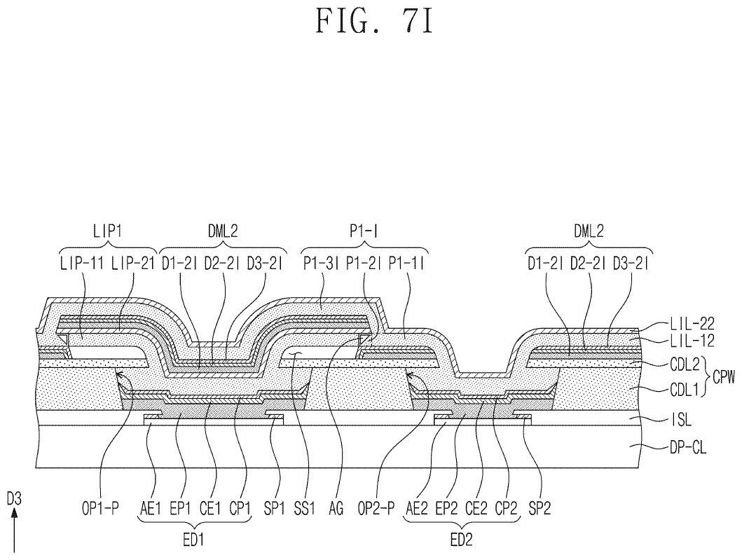

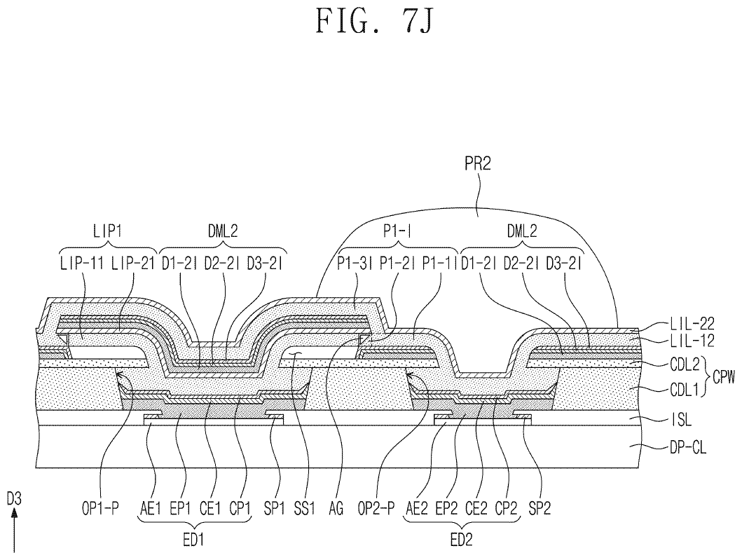

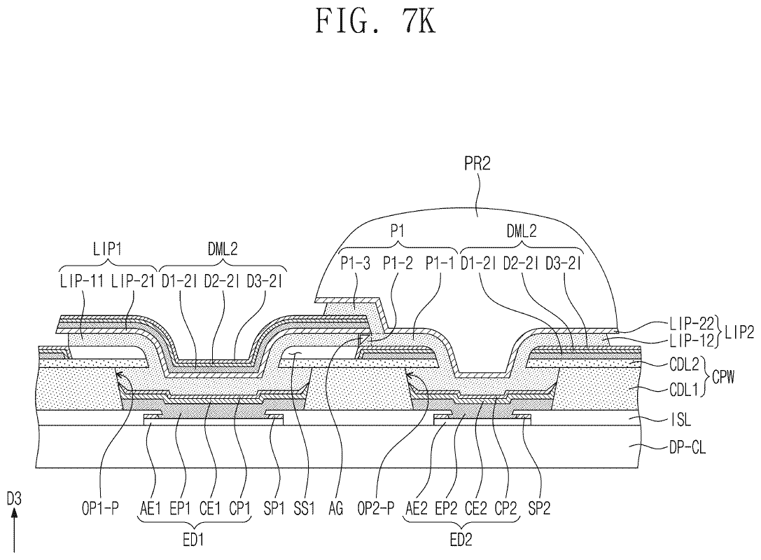

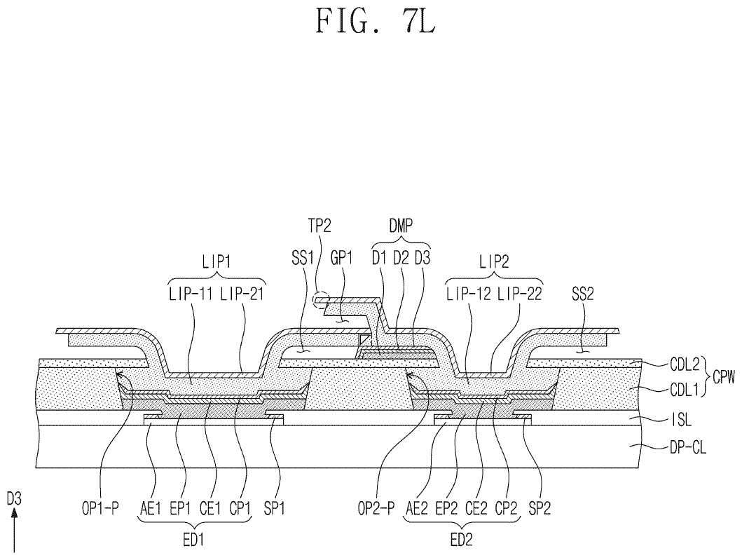

FIGS. 7A-7L are cross-sectional views illustrating steps of a method of manufacturing the display panel according to one or more embodiments of the present disclosure. In describing FIGS. 7A-7L, the same/similar reference numerals will be used for the same/similar components as those described with reference to FIGS. 1A-6C, and duplicate descriptions will be omitted.

The method of manufacturing the display panel according to the present disclosure includes: providing a preliminary display panel including a base layer and a preliminary bank layer disposed on the base layer, having a first pixel opening and a second pixel opening defined therein, and including a conductive material; forming a first light-emitting element in the first pixel opening; forming a (1-1)-th preliminary lower encapsulation layer covering the first light-emitting element and the preliminary bank layer; forming a (2-1)-th preliminary lower encapsulation layer including a material different from that of the (1-1)-th preliminary lower encapsulation layer on the (1-1)-th preliminary lower encapsulation layer; patterning the (1-1)-th preliminary lower encapsulation layer and the (2-1) preliminary lower encapsulation layer to form a (1-1)-th lower encapsulation pattern and a (2-1)-th lower encapsulation pattern partially overlapping the first pixel opening; forming a second light-emitting element in the second pixel opening; forming a (1-2)-th preliminary lower encapsulation layer covering the second light-emitting element and the preliminary bank layer; forming a (2-2)-th preliminary lower encapsulation layer including a material different from that of the (1-2)-th preliminary lower encapsulation layer on the (1-2)-th preliminary lower encapsulation layer; and patterning the (1-2)-th preliminary lower encapsulation layer and the (2-2)-th preliminary lower encapsulation layer to form a (1-2)-th lower encapsulation pattern and a (2-2)-th lower encapsulation pattern partially overlapping the second pixel opening.

Referring to FIG. 7A, the method of manufacturing the display panel according to one or more embodiments of the present disclosure includes providing a preliminary display panel, wherein the preliminary display panel includes first and second anodes AE1 and AE2 disposed on the base layer, a pixel defining film ISL disposed on the base layer and partially covering the first and second anodes AE1 and AE2, and a bank layer CPW disposed on the pixel defining film ISL and including a conductive material. The base layer BL (see FIG. 6A) is not illustrated in FIG. 7A, but a base layer may be disposed below the circuit element layer DP-CL.

The circuit element layer DP-CL may be formed through a typical circuit element manufacturing process in which an insulating layer, a semiconductor layer, and a conductive layer are formed by a method such as coating and deposition, and then the insulating layer, the semiconductor layer, and the conductive layer are selectively patterned through photolithography and etching processes to form a semiconductor pattern, a conductive pattern, a signal line and the like.

The first and second anodes AE1 and AE2 may be formed on the sixth insulating layer 60 (see FIG. 6A) of the circuit element layer DP-CL. The first and second sacrificial patterns SP1 and SP2 may be respectively formed on the first and second anodes AE1 and AE2.

The bank layer CPW may include a double-layer structure, the description of the first conductive layer CDL1 described above with reference to FIG. 6B may be applied to the first conductive layer CDL1, and the description of the second conductive layer CDL2 described above with reference to FIG. 6B may be applied to the second conductive layer CDL2. The first conductive layer CDL1 may have a first conductivity and a first thickness, and the second conductive layer CDL2 may have a second conductivity lower than the first conductivity and a second thickness smaller than the first thickness.

The providing of the preliminary display panel may include forming a first pixel opening OP1-P corresponding to the first anode AE1 and exposing the upper surface of the first anode AE1 and a second pixel opening OP2-P corresponding to the second anode AE2 and exposing the upper surface of the second anode AE2. In the forming of the first pixel opening OP1-P, a light-emitting opening OP1-E (see FIG. 6A) corresponding to the first pixel opening OP1-P may be formed, and a sacrificial opening OP1-L (see FIG. 6A) corresponding to the first pixel opening OP1-P may be formed to form a first sacrificial pattern SP1. In the forming of the second pixel opening OP2-P, a light-emitting opening OP2-E (see FIG. 6B) corresponding to the second pixel opening OP2-P may be formed, and a sacrificial opening OP2-L (see FIG. 6A that shows OP1-L) corresponding to the second pixel opening OP2-P may be formed to form a second sacrificial pattern SP2.

Referring to FIGS. 7A and 7B, the method of manufacturing the display panel according to one or more embodiments includes sequentially forming a first light-emitting pattern EP1 and a first cathode CE1 on the first anode AE1 in the first pixel opening OP1-P to form a first light-emitting element ED1. The method of manufacturing the display panel according to one or more embodiments includes forming a (1-1)-th preliminary lower encapsulation layer LIL-11 covering the first light-emitting element ED1 and the bank layer CPW after the forming of the first light-emitting element ED1.

In the forming of the first light-emitting element ED1, a first capping pattern CP1 may be additionally formed on the first cathode CE1. The first capping pattern CP1 may be formed to be disposed in the first pixel opening OP1-P.

In the forming of the first light-emitting element ED1, a first preliminary dummy layer DML1 may be formed on the bank layer CPW. The first preliminary dummy layer DML1 may be formed through the same process as the first light-emitting element ED1. The first preliminary dummy layer DML1 may include a (1-1)-th dummy layer D1-1I, a (2-1)-th dummy layer D2-1I, and a (3-1)-th dummy layer D3-1I. The (1-1)-th dummy layer D1-1I may be formed through the same process as the first light-emitting pattern EP1, the (2-1)-th dummy layer D2-1I may be formed through the same process as the first cathode CE1, and the (3-1) dummy layer D3-1I may be formed through the same process as the first capping pattern CP1. The first preliminary dummy layer DML1 may be formed separately from the first light-emitting element ED1 by the second bank layer CDL2 which forms a tip structure.

In the forming of the first light-emitting element ED1, a preliminary dummy pattern DMP1 may be formed in the second pixel opening OP2-P. The preliminary dummy pattern DMP1 may be formed through the same process as the first light-emitting element ED1. The preliminary dummy pattern DMP1 may include a (1-1)-th dummy pattern D1-1P, a (2-1)-th dummy pattern D2-1P, and a (3-1)-th dummy pattern D3-1P. The (1-1)-th dummy pattern D1-1P may be formed through the same process as the first light-emitting pattern EP1, the (2-1)-th dummy pattern D2-1P may be formed through the same process as the first cathode CE1, and the (3-1)-th dummy pattern D3-1P may be formed through the same process as the first capping pattern CP1.

The (1-1)-th preliminary lower encapsulation layer LIL-11 may cover the first light-emitting element ED1 and the first preliminary dummy layer DML1. A portion of the (1-1)-th preliminary lower encapsulation layer LIL-11 may be disposed in the first pixel opening OP1-P. The (1-1)-th preliminary lower encapsulation layer LIL-11 may come in contact with the upper surface of the first capping pattern CP1 and the upper surface of the (3-1)-th dummy layer D3-1I. A portion of the (1-1)-th preliminary lower encapsulation layer LIL-11 may be disposed in the second pixel opening OP2-P and cover the preliminary dummy pattern DMP1.

The (1-1)-th preliminary lower encapsulation layer LIL-11 is formed of the first material described above. The first material may include an inorganic material such as silicon nitride, silicon oxynitride, silicon oxide, titanium oxide, and/or aluminum oxide. The (1-1)-th preliminary lower encapsulation layer LIL-11 may be formed by a chemical vapor deposition (CVD) method.

Referring to FIGS. 7B and 7C, a (2-1)-th preliminary lower encapsulation layer LIL-21 is formed on the (1-1)-th preliminary lower encapsulation layer LIL-11. The (2-1)-th preliminary lower encapsulation layer LIL-21 is formed of a second material different from the first material. The second material may have an etch rate different from that of the first material. The second material may have a lower etch rate than the first material in an etching process that uses a photoresist pattern PR1 (see FIG. 7D), which will be described later. The second material may include, for example, silicon oxynitride (SiON), indium zinc oxide (IZO), and/or indium gallium zinc oxide (IGZO). Alternatively, the second material may include a metallic material.

Referring to FIGS. 7C to 7E, the method of manufacturing the display panel according to one or more embodiments may include forming a first photoresist pattern PR1 at least partially overlapping the first light-emitting element ED1 on the (2-1)-th preliminary lower encapsulation layer LIL-21.

The first photoresist pattern PR1 is disposed on the (2-1)-th preliminary lower encapsulation layer LIL-21 and may be disposed to overlap at least the first light-emitting element ED1. The first photoresist pattern PR1 may be disposed to correspond to the first pixel opening OP1-P.

The method of manufacturing the display panel according to one or more embodiments includes patterning the (1-1)-th preliminary lower encapsulation layer LIL-11 and the (2-1)-th preliminary lower encapsulation layer LIL-21 to form a first pixel encapsulation pattern LIP1. The first pixel encapsulation pattern LIP1 includes a (1-1)-th lower encapsulation pattern LIP-11 and a (2-1)-th lower encapsulation pattern LIP-21. The first pixel encapsulation pattern LIP1 may be formed to overlap at least the first pixel opening OP1-P. The first pixel encapsulation pattern LIP1 may overlap the first light-emitting element ED1, and a portion of the first pixel encapsulation pattern LIP1 may be disposed on the bank layer CPW.

In the forming of the first pixel encapsulation pattern LIP1, the (1-1)-th preliminary lower encapsulation layer LIL-11 and the (2-1)-th preliminary lower encapsulation layer LIL-21 may be etched by using the first photoresist pattern PR1 as a mask.

Referring to FIGS. 7E and 7F, after the forming of the first pixel encapsulation pattern LIP1, the first photoresist pattern PR1 may be removed. In the process of removing the first photoresist pattern PR1, the first preliminary dummy layer DML1 and the preliminary dummy pattern DMP1 may be removed together. As the first preliminary dummy layer DML1 and the preliminary dummy pattern DMP1 are removed, a suitable first separation portion (e.g., a predetermined first separation portion) SS1 may be defined between the first pixel encapsulation pattern LIP1 and the bank layer CPW. That is, the (1-1)-th lower encapsulation pattern LIP1 and the second bank layer CDL2 may be disposed to be spaced from each other, and the first separation portion SS1 may be defined between them.

In the forming of the first pixel encapsulation pattern LIP1 described above, due to a difference in etch rate between materials included in the (1-1)-th preliminary lower encapsulation layer LIL-11 and the (2-1)-th preliminary lower encapsulation layer LIL-21, a first tip portion TP1 may be formed in the (2-1)-th lower encapsulation pattern LIP-21 disposed above. The first tip portion TP1 may have a shape that protrudes from the (1-1)-th lower encapsulation pattern LIP-11.

Referring to FIGS. 7F and 7G, the method of manufacturing the display panel according to one or more embodiments includes sequentially forming a second light-emitting pattern EP2 and a second cathode CE2 on the second anode AE2 in the second pixel opening OP2-P to form a second light-emitting element ED2.

In the forming of the second light-emitting element ED2, a second capping pattern CP2 may be additionally formed on the second cathode CE2. The second capping pattern CP2 may be formed to be disposed in the second pixel opening OP2-P.

In the forming of the second light-emitting element ED2, a second preliminary dummy layer DML2 may be formed on the bank layer CPW. The second preliminary dummy layer DML2 may be formed through the same process as the second light-emitting element ED2. The second preliminary dummy layer DML2 may include a (1-2)-th dummy layer D1-2I, a (2-2)-th dummy layer D2-2I, and a (3-2)-th dummy layer D3-2I. The (1-2)-th dummy layer D1-2I may be formed through the same process as the second light-emitting pattern EP2, the (2-2)-th dummy layer D2-2I may be formed through the same process as the second cathode CE2, and the (3-2)-th dummy layer D3-21 may be formed through the same process as the second capping pattern CP2. The second preliminary dummy layer DML2 may be formed separately from the second light-emitting element ED2 by the second bank layer CDL2 which forms a tip structure.

In the forming of the second light-emitting element ED2, the second preliminary dummy layer DML2 may be formed on the first pixel encapsulation pattern LIP1 as well as on the bank layer CPW. A portion of the second preliminary dummy layer DML2 may be formed on the (2-1)-th lower encapsulation pattern LIP-21 included in the first pixel encapsulation pattern LIP1. Due to the first tip portion TP1 included in the (2-1)-th lower encapsulation pattern LIP-21, the second preliminary dummy layer DML2 formed on the (2-1)-th lower encapsulation pattern LIP-21 and the second preliminary dummy layer DML2 formed on the bank layer CPW may not be connected to each other and may have a disconnected shape. That is, the second preliminary dummy layer DML2 may be patterned and formed on the (2-1)-th lower encapsulation pattern LIP-21 and the bank layer CPW.

Referring to FIGS. 7G and 7H, the method of manufacturing the display panel according to one or more embodiments includes forming a (1-2)-th preliminary lower encapsulation layer LIL-12 covering the second light-emitting element ED2 and the bank layer CPW after the forming of the second light-emitting element ED2.

The (1-2)-th preliminary lower encapsulation layer LIL-12 may cover the second light-emitting element ED2 and the second preliminary dummy layer DML2. A portion of the (1-2)-th preliminary lower encapsulation layer LIL-12 may be disposed in the second pixel opening OP2-P. The (1-2)-th preliminary lower encapsulation layer LIL-12 may come in contact with the upper surface of the second capping pattern CP2 and the upper surface of the (3-2)-th dummy layer D3-2I.

The (1-2)-th preliminary lower encapsulation layer LIL-12 is formed of the first material described above. The first material may include an inorganic material such as silicon nitride, silicon oxynitride, silicon oxide, titanium oxide, and/or aluminum oxide. The (1-2)-th preliminary lower encapsulation layer LIL-12 may be formed by a chemical vapor deposition (CVD) method.

The (1-2)-th preliminary lower encapsulation layer LIL-12 may include a first portion P1-I disposed on the second preliminary dummy layer DML2, wherein the first portion P1-I may include a (1-1)-th portion P1-1I, a (1-2)-th portion P1-2I, and a (1-3)-th portion P1-3I.

For the convenience of explanation, the (1-1)-th portion P1-1I, the (1-2)-th portion P1-2I, and the (1-3)-th portion P1-3I are described as separate components, but the (1-1)-th portion P1-1I, the (1-2)-th portion P1-2I, and the (1-3)-th portion P1-3I may not be components separated from each other with interfaces interposed therebetween and may have an integral shape.

The (1-1)-th portion P1-1I may be disposed on the bank layer CPW and the second preliminary dummy layer DML2 and may not overlap the (2-1)-th lower encapsulation pattern LIP-21. The (1-2)-th portion P1-2I may be disposed on the bank layer CPW and the second preliminary dummy layer DML2 and may be disposed below the first tip portion TP1 defined in the (2-1)-th lower encapsulation pattern LIP-21. The (1-2)-th portion P1-2I may be disposed below the (2-1)-th lower encapsulation pattern LIP-21 and be in contact with the (1-1)-th lower encapsulation pattern LIP-11.

In one or more embodiments, an air gap AG may be defined in the (1-2)-th portion P1-2I. The air gap AG is formed in the (1-2)-th portion P1-2I, and the air gap AG may be formed by the first tip portion TP1 in the process of forming the (1-2)-th lower encapsulation pattern LIP-12. As the (1-2)-th preliminary lower encapsulation layer LIL-12 is formed by a chemical vapor deposition method, the (1-2)-th portion P1-2I may be formed to come in contact with the (1-1)-th lower encapsulation pattern LIP-11 in the form of a thin film, and the air gap AG may be provided in the (1-2)-th portion P1-2I. As described above, as the second preliminary dummy layer DML2 has a disconnected shape due to the first tip portion TP1, a portion of the (1-2)-th preliminary lower encapsulation layer LIL-12 formed by a chemical vapor deposition method may be formed to be in contact with the (1-1)-th lower encapsulation pattern LIP-11.

The (1-3)-th portion P1-3I may be disposed above the (2-1)-th lower encapsulation pattern LIP-21. The (1-3)-th portion P1-3I may be disposed on the second preliminary dummy layer DML2 disposed on the (2-1)-th lower encapsulation pattern LIP-21.

Referring to FIGS. 7H and 7I, a (2-2)-th preliminary lower encapsulation layer LIL-22 is formed on the (1-2)-th preliminary lower encapsulation layer LIL-12. The (2-2)-th preliminary lower encapsulation layer LIL-22 is formed of a second material different from the first material. The second material may have an etch rate different from that of the first material. The second material may have a lower etch rate than the first material in an etching process which uses a photoresist pattern PR2 (see FIG. 7J), which will be described later. The second material may include, for example, silicon oxynitride (SiON), indium zinc oxide (IZO), and/or indium gallium zinc oxide (IGZO). Alternatively, the second material may include a metallic material.

Referring to FIGS. 7I to 7K, the method of manufacturing the display panel according to one or more embodiments of the inventive concept may include forming a second photoresist pattern PR2 at least partially overlapping the second light-emitting element ED2 on the (2-2)-th preliminary lower encapsulation layer LIL-22.

The second photoresist pattern PR2 is disposed on the (2-2)-th preliminary lower encapsulation layer LIL-22 and may be disposed to overlap at least the second light-emitting element ED2. The second photoresist pattern PR2 may be disposed to correspond to the second pixel opening OP2-P. The second photoresist pattern PR2 may be provided to overlap at least the first portion P1-1.

The method of manufacturing the display panel according to one or more embodiments includes patterning the (1-2)-th preliminary lower encapsulation layer LIL-12 and the (2-2)-th preliminary lower encapsulation layer LIL-22 to form a second pixel encapsulation pattern LIP2. The second pixel encapsulation pattern LIP2 includes a (1-2)-th lower encapsulation pattern LIP-12 and a (2-2)-th lower encapsulation pattern LIP-22. The second pixel encapsulation pattern LIP2 may be formed to overlap at least the second pixel opening OP2-P. The second pixel encapsulation pattern LIP2 may overlap the second light-emitting element ED2, and a portion of the second pixel encapsulation pattern LIP2 may be disposed on the bank layer CPW.

In the forming of the second pixel encapsulation pattern LIP2, the (1-2)-th preliminary lower encapsulation layer LIL-12 and the (2-2)-th preliminary lower encapsulation layer LIL-22 may be etched by using the second photoresist pattern PR2 as a mask.

A portion of the second pixel encapsulation pattern LIP2 is formed to overlap the first pixel encapsulation pattern LIP1 described above. The second pixel encapsulation pattern LIP2 may include the first portion P1, and the (1-2)-th portion P1-2 may be disposed below the first tip portion TP1 defined in the (2-1)-th lower encapsulation pattern LIP-21. The (1-2)-th portion P1-2 may be disposed below the (2-1)-th lower encapsulation pattern LIP-21 and may be in contact with the (1-1)-th lower encapsulation pattern LIP-11. The (1-3)-th portion P1-3 may be disposed on the (2-1)-th lower encapsulation pattern LIP-21. The (1-3)-th portion P1-3 may be disposed on the second preliminary dummy layer DML2 disposed on the (2-1)-th lower encapsulation pattern LIP-21.

Referring to FIGS. 7K and 7L, after the forming of the second pixel encapsulation pattern LIP2, the second photoresist pattern PR2 may be removed. In the process of removing the second photoresist pattern PR2, at least a portion of the second preliminary dummy layer DML2 may be removed together. As the second preliminary dummy layer DML2 is removed, a suitable second separation portion (e.g., a predetermined second separation portion) SS2 may be defined between the second pixel encapsulation pattern LIP2 and the bank layer CPW. That is, the (1-2)-th lower encapsulation pattern LIP12 and the second bank layer CDL2 may be disposed to be spaced from each other, and the second separation portion SS2 may be defined between them.

A portion of the second preliminary dummy layer DML2 may be maintained without being removed and form a dummy pattern DMP due to a structure in which a portion of the (1-2)-th preliminary lower encapsulation layer LIL-12 is in contact with the (1-1)-th lower encapsulation pattern LIP-11. The dummy pattern DMP may be formed below the (1-1)-th portion P1-1 and the (1-2)-th portion P1-2 which are described above.

In the forming of the second pixel encapsulation pattern LIP2, due to a difference in etch rate between materials included in the (1-2)-th preliminary lower encapsulation layer LIL-12 and the (2-2)-th preliminary lower encapsulation layer LIL-22, a second tip portion TP2 may be formed in the (2-2)-th lower encapsulation pattern LIP-22 disposed above. The second tip portion TP2 may have a shape that protrudes from the (1-2)-th lower encapsulation pattern LIP-12.

Although not illustrated, a third anode AE3 (see FIG. 6B) and a third pixel opening OP3-P (see FIG. 6B) corresponding thereto may be provided in the preliminary display panel described above, and the method of manufacturing the display panel according to one or more embodiments may further include forming a third light-emitting element ED3 (see FIG. 6B) corresponding to the third pixel opening and forming a third pixel encapsulation pattern LIP3 on the third light-emitting element. The aforementioned descriptions on the forming of the second light-emitting element and the second pixel encapsulation pattern may be similarly applied to the forming of the third light-emitting element and the third pixel encapsulation pattern, respectively.

The method of manufacturing the display panel according to one or more embodiments of the present disclosure may include sequentially forming an organic encapsulation film OL and an upper inorganic encapsulation film UIL on the lower encapsulation patterns LIP1 and LIP2. The organic encapsulation film OL may be formed to cover an inorganic film IOL, have a large thickness, and provide a flat upper surface. The upper inorganic encapsulation film UIL may prevent moisture/oxygen from entering and improve the durability of the display panel.

The display panel according to one or more embodiments of the present disclosure may prevent not only the occurrence of a defect in which the encapsulation patterns that protect the light-emitting elements are lost in the middle of a process, but also the occurrence of a defect in which the light-emitting patterns of the light-emitting elements are damaged due to the entry of moisture and the like, thus improving the durability and reliability of the display panel.

Although the above has been described with reference to embodiments of the present disclosure, those skilled in the art or those of ordinary skill in the art will understand that various modifications and changes can be made to the present disclosure within the scope that does not depart from the spirit and technical field of the inventive concept described in the claims to be described later. Accordingly, the technical scope of the present disclosure should not be limited to the content described in the detailed description of the specification, but should be determined by the claims described hereinafter.

What is claimed is:

1. A display panel comprising:
a base layer;
a pixel defining film on the base layer and comprising an inorganic material;
a bank layer on the pixel defining film and having a plurality of pixel openings;
a plurality of light-emitting elements respectively located in the plurality of pixel openings, each of the plurality of light-emitting elements comprising an anode, a light-emitting pattern, and a cathode, the cathode being in contact with the bank layer; and
a lower encapsulation pattern on the bank layer and comprising a portion on the bank layer,
wherein the lower encapsulation pattern comprises:
a first lower encapsulation pattern on the cathode and the bank layer, the first lower encapsulation pattern comprising a first material; and
a second lower encapsulation pattern on the first lower encapsulation pattern, the second lower encapsulation pattern comprising a second material different from the first material and a tip portion protruding in a direction away from a side surface of the first lower encapsulation pattern.

2. The display panel of claim 1, wherein:
the plurality of pixel openings comprises a first pixel opening and a second pixel opening that are spaced from each other; and
the plurality of light-emitting elements comprises a first light-emitting element in the first pixel opening and comprising a first anode, a first light-emitting pattern, and a first cathode, and a second light-emitting element in the second pixel opening and comprising a second anode, a second light-emitting pattern, and a second cathode.

3. The display panel of claim 2, wherein the lower encapsulation pattern comprises:
a first pixel encapsulation pattern on the first cathode; and
a second pixel encapsulation pattern on the second cathode,
wherein the first pixel encapsulation pattern comprises:
a (1-1)-th lower encapsulation pattern on the first cathode and comprising the first material; and
a (2-1)-th lower encapsulation pattern on the (1-1)-th lower encapsulation pattern, the (2-1)-th lower encapsulation pattern comprising the second material and a first tip portion protruding in a direction away from a side surface of the (1-1)-th lower encapsulation pattern,
wherein the second pixel encapsulation pattern comprises:
a (1-2)-th lower encapsulation pattern on the second cathode and comprising the first material; and
a (2-2)-th lower encapsulation pattern on the (1-2)-th lower encapsulation pattern, the (2-2)-th lower encapsulation pattern comprising the second material and a second tip portion protruding in a direction away from a side surface of the (1-2)-th lower encapsulation pattern.

4. The display panel of claim 3, wherein a portion of the (1-2)-th lower encapsulation pattern is located below the (2-1)-th lower encapsulation pattern and is in contact with the (1-1)-th lower encapsulation pattern.

5. The display panel of claim 3, wherein the (1-2)-th lower encapsulation pattern comprises a first portion on the bank layer,
wherein the first portion comprises:
a (1-1)-th portion that does not overlap the (2-1)-th lower encapsulation pattern on a plane; and
a (1-2)-th portion below the (2-1)-th lower encapsulation pattern and in contact with the (1-1)-th lower encapsulation pattern,
wherein an air gap is defined in the (1-2)-th portion.

6. The display panel of claim 5, wherein the first portion further comprises a (1-3)-th portion on the (2-1)-th lower encapsulation pattern,
wherein the (1-3)-th portion is spaced from the (2-1)-th lower encapsulation pattern at a predetermined distance.

7. The display panel of claim 5, further comprising a dummy pattern between the first portion and the bank layer and adjacent to the second pixel opening,
wherein the dummy pattern is separated from the second light-emitting pattern and the second cathode.

8. The display panel of claim 3, wherein a portion of the (1-1)-th lower encapsulation pattern is on the bank layer, and a predetermined separation portion is defined between the bank layer and the portion of the (1-1)-th lower encapsulation pattern.

9. The display panel of claim 3, wherein:
the plurality of pixel openings further comprises a third pixel opening spaced from each of the first pixel opening and the second pixel opening;
the plurality of light-emitting element further comprises a third light-emitting element in the third pixel opening and comprising a third anode, a third light-emitting pattern, and a third cathode; and
the lower encapsulation pattern further comprises a third pixel encapsulation pattern on the third cathode.

10. The display panel of claim 9, wherein the third pixel encapsulation pattern comprises:
a (1-3)-th lower encapsulation pattern on the third cathode and comprising the first material; and
a (2-3)-th lower encapsulation pattern on the (1-3)-th lower encapsulation pattern, the (2-3)-th lower encapsulation pattern comprising the second material and a third tip portion protruding in a direction away from a side surface of the (1-3)-th lower encapsulation pattern,
wherein a portion of the (1-3)-th lower encapsulation pattern is below the (2-2)-th lower encapsulation pattern and is in contact with the (1-2)-th lower encapsulation pattern.

11. The display panel of claim 1, wherein the second material comprises silicon oxynitride, indium zinc oxide, indium gallium zinc oxide, and/or a metallic material.

12. The display panel of claim 1, wherein:
a portion of the first lower encapsulation pattern is directly on the cathode; and
a portion of the second lower encapsulation pattern is directly on the first lower encapsulation pattern.

13. The display panel of claim 1, wherein each of the plurality of light-emitting elements further comprises a capping pattern on the cathode.

14. The display panel of claim 1, further comprising:
an organic encapsulation film on the second lower encapsulation pattern and providing a flat upper surface; and
an upper inorganic encapsulation film on the organic encapsulation film.

15. The display panel of claim 1, wherein the bank layer comprises:
a first conductive layer on the pixel defining film; and
a second conductive layer on the first conductive layer and having an undercut shape protruding from one side of the first conductive layer.

16. A display panel comprising:
a base layer;
a pixel defining film on the base layer and comprising an inorganic material;
a bank layer on the pixel defining film and having a first pixel opening and a second pixel opening that are spaced from each other;
a plurality of light-emitting elements comprising a first light-emitting element in the first pixel opening and a second light-emitting element in the second pixel opening; and
a lower encapsulation pattern comprising a first pixel encapsulation pattern on the first light-emitting element and a second pixel encapsulation pattern on the second light-emitting element,
wherein the first pixel encapsulation pattern comprises:
a (1-1)-th lower encapsulation pattern on the first light-emitting element; and
a (2-1)-th lower encapsulation pattern on the (1-1)-th lower encapsulation pattern and including a first tip portion protruding in a direction away from a side surface of the (1-1)-th lower encapsulation pattern,
wherein the second pixel encapsulation pattern comprises:
a (1-2)-th lower encapsulation pattern on the second light-emitting element; and
a (2-2)-th lower encapsulation pattern on the (1-2)-th lower encapsulation pattern and including a second tip portion protruding in a direction away from a side surface of the (1-2)-th lower encapsulation pattern,
wherein a portion of the (1-2)-th lower encapsulation pattern is located below the (2-1)-th lower encapsulation pattern and is in contact with the (1-1)-th lower encapsulation pattern.

17. A method for manufacturing a display panel, the method comprising:
providing a preliminary display panel comprising a base layer and a bank layer on the base layer, the display panel having a first pixel opening and a second pixel opening, and comprising a conductive material;
forming a first light-emitting element in the first pixel opening;
forming a (1-1)-th preliminary lower encapsulation layer covering the first light-emitting element and the bank layer;
forming a (2-1)-th preliminary lower encapsulation layer comprising a material different from that of the (1-1)-th preliminary lower encapsulation layer on the (1-1)-th preliminary lower encapsulation layer;
patterning the (1-1)-th preliminary lower encapsulation layer and the (2-1)-th preliminary lower encapsulation layer to form a (1-1)-th lower encapsulation pattern and a (2-1)-th lower encapsulation pattern partially overlapping the first pixel opening;
forming a second light-emitting element in the second pixel opening;
forming a (1-2)-th preliminary lower encapsulation layer covering the second light-emitting element and the bank layer;
forming a (2-2)-th preliminary lower encapsulation layer comprising a material different from that of the (1-2)-th preliminary lower encapsulation layer on the (1-2)-th preliminary lower encapsulation layer; and
patterning the (1-2)-th preliminary lower encapsulation layer and the (2-2)-th preliminary lower encapsulation layer to form a (1-2)-th lower encapsulation pattern and a (2-2)-th lower encapsulation pattern partially overlapping the second pixel opening,
wherein a portion of the (1-2)-th lower encapsulation pattern is located below the (2-1)-th lower encapsulation pattern and is in contact with the (1-1)-th lower encapsulation pattern.

18. The method of claim 17, further comprising forming a first photoresist pattern at least partially overlapping the first pixel opening on the (2-1)-th preliminary lower encapsulation layer prior to the patterning of the (1-1)-th preliminary lower encapsulation layer and the (2-1)-th preliminary lower encapsulation layer,
wherein the first photoresist pattern is removed after the (1-1)-th lower encapsulation pattern and the (2-1)-th lower encapsulation pattern are formed.

19. The method of claim 18, wherein, in the forming of the first light-emitting element, a first preliminary dummy layer is formed on the bank layer,
wherein the first preliminary dummy layer is removed together when the first photoresist pattern is removed.

20. The method of claim 17, wherein, in the forming of the (1-2)-th lower encapsulation pattern and the (2-2)-th lower encapsulation pattern, a portion of the (1-2)-th lower encapsulation pattern is on the (1-1)-th lower encapsulation pattern and the (2-1)-th lower encapsulation pattern.
